(19) United States
(12) Patent Application Publication
(10) Pub. No.: US 2005/0253205 A1
(43) Pub. Date: Nov. 17, 2005

(54) Semiconductor device and method for fabricating the same

(75) Inventor: Kazuo Kawamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/004,805

(22) Filed: Dec. 7, 2004

(30) Foreign Application Priority Data
May 17, 2004 (JP) 2004-146763
Oct. 7, 2004 (JP) 2004-294855

(51) Int. Cl. H01L 29/76

(52) U.S. Cl. 257/412

(57) ABSTRACT

The method for fabricating a semiconductor device comprises the step of forming an Ni film 66 on a source/drain diffused layers 64, the first thermal processing step of reacting a part of the Ni film 66 on the lower side and a part of the source/drain diffused layers 64 on the upper side with each other by thermal processing to form Ni₂Si films 70b on the source/drain diffused layers 64, and the step of etching off the part of the Ni film 66, which has not reacted, and the second thermal processing of reacting by thermal processing the Ni₂Si films 70b and parts of the source/drain diffused layers 64 on the upper side with each other.

### CROSS-REFERENCE TO RELATED APPLICATIONS

This application is based upon and claims priorities of Japanese Patent Application No. 2004-146763, filed on May 17, 2004, and Japanese Patent Application No. 2004-294855, filed on Oct. 7, 2004, the contents being incorporated herein by reference.

### BACKGROUND OF THE INVENTION

The present invention relates to a semiconductor device and a method for fabricating the same, more specifically, a semiconductor device and a method for fabricating the same in which silicidation using nickel is performed.

As a technique of making gate electrodes and source/drain diffused layers less resistive is known the so-called salicide (Self-Aligned Silicide) process for forming metal silicide film by self-alignment on the surfaces of the gate electrode and the source/drain diffused layers. As a metal material which is reacted with silicon in the salicide process, cobalt (Co) is widely used (refer to, e.g., Japanese published unexamined patent application No. Hei 09-251967 (1997)).

On the other hand, the micronization of structures of semiconductor devices are rapidly being advanced. To be specific, the junction depth of source/drain diffused layers are as small as below 80 nm excluding 80 nm. The film thickness of metal silicide films formed on the source/drain diffused layers is as small as below 20 nm excluding 20 nm. Gate lengths are as small as below 50 nm excluding 50 nm.

In such increasing micronization of structures of semiconductor devices, when a semiconductor device of a gate length of below 40 nm excluding 40 nm, and a CoSi₂ film is formed on the gate electrode using a Co film, the phenomena that dispersions of the resistance of the gate electrodes abruptly increase is confirmed.

In contrast to such CoSi₂, nickel silicide has the merit that even when the gate length is below 40 nm excluding 40 nm, the resistance of the gate electrodes is stable, and is much noted.

However, when the silicidation is performed with Ni film simply used, the roughness of the interface between the silicon layer and silicide film is so large that dispersions of the sheet resistance of the source/drain diffused layer are increased, and the junction leak current is often increased.

### SUMMARY OF THE INVENTION

An object of the present invention is to provide a semiconductor device which can suppress the dispersion of the sheet resistance of the source/drain diffused layers and the junction leak current, and a method for fabricating the same.

According to one aspect of the present invention, there is provided a semiconductor device comprising: a gate electrode formed on a semiconductor substrate; a source/drain diffused layer formed in the semiconductor substrate on both sides of the gate electrode; and a silicide film formed on the source/drain diffused layer, the silicide film being formed of nickel monosilicide, and a film thickness of the silicide film being below 20 nm including 20 nm.

According to another aspect of the present invention, there is provided a method for fabricating a semiconductor device comprising: the step of forming a gate electrode on a semiconductor substrate; the step of forming a source/drain diffused layer in the semiconductor substrate on both sides of the gate electrode; the step of forming a nickel film on the source/drain diffused layer; the first thermal processing step of reacting by thermal processing a part of the nickel film on the lower side and a part of the source/drain diffused layer on the upper side with each other to form a nickel silicide film on the source/drain diffused layer; the step of etching off selectively a part of the nickel film, which has not reacted; and the second thermal processing step of reacting further the nickel silicide film and a part of the source/drain diffused layer on the upper side with each other.

According to the present invention, by the first thermal processing, a part of a relatively thick nickel film on the lower side and a part of a silicon substrate on the upper side are reacted with each other, whereby in the first thermal processing, an Ni₂Si film can be formed while the formation of NiSi₂ crystals is suppressed. Then, in the present invention, a part of the nickel film, which has not reacted with the Si is selectively etched off, and then, by the second thermal processing the Ni₂Si film and a part of the silicon substrate on the upper side are reacted with each other to form an NiSi film, whereby the NiSi film is prevented from being forming in a too large thickness. Furthermore, according to the present invention, conditions for the first and the second thermal processing are suitably set, whereby the film thickness of the NiSi film can be controlled. Thus, according to the present invention, the formation of the NiSi₂ film of high resistance is suppressed while an NiSi film of good quality and low resistance can be formed on a silicon substrate. Thus, when the surface of the gate electrode and the surface of the source/drain diffused layers are silcidied, the dispersions of the sheet resistance can be suppressed. The junction leak current can be also suppressed.

### BRIEF DESCRIPTION OF THE DRAWINGS

FIGS. 1A-1E are diagrammatic sectional views of a reaction model of the silicidation process for nickel silicide (Part 1).

FIGS. 2A-2D are diagrammatic sectional views of a reaction model of the silicidation process for nickel silicide (Part 2).

FIG. 3 is a diagrammatic sectional view of a MOS transistor subjected to salicide process using a relatively thin Ni film, which illustrates a structure of the MOS transistor.

FIG. 4 is a graph of the results of an experiment in which the sheet resistance of source/drain diffused layers silicided using Ni film of different film thicknesses.

FIGS. 5A-5D are diagrammatic sectional views illustrating the principle of the present invention.

FIG. 6 is a graph schematically showing the relationships between the Gibbs' free energy of the system of a silicon substrate and a nickel silicide film, and the film thickness of an Ni film.

FIG. 7 is a sectional view of the semiconductor device according to a first embodiment of the present invention, which illustrates a structure thereof.

FIGS. 8A-8C are sectional views of the semiconductor device according to the first embodiment of the present invention in the steps of the method for fabricating the same, which illustrate the method (Part 1).

FIGS. 9A-9C are sectional views of the semiconductor device according to the first embodiment of the present invention in the steps of the method for fabricating the same, which illustrate the method (Part 2).

FIGS. 10A-10C are sectional views of the semiconductor device according to the first embodiment of the present invention in the steps of the method for fabricating the same, which illustrate the method (Part 3).

FIGS. 11A-11C are sectional views of the semiconductor device according to the first embodiment of the present invention in the steps of the method for fabricating the same, which illustrate the method (Part 4).

FIGS. 12A-12C are sectional views of the semiconductor device according to the first embodiment of the present invention in the steps of the method for fabricating the same, which illustrate the method (Part 5).

FIGS. 13A-13C are sectional views of the semiconductor device according to the first embodiment of the present invention in the steps of the method for fabricating the same, which illustrate the method (Part 6).

FIGS. 14A-14C are sectional views of the semiconductor device according to the first embodiment of the present invention in the steps of the method for fabricating the same, which illustrate the method (Part 7).

FIGS. 15A-15C are sectional views of the semiconductor device according to the first embodiment of the present invention in the steps of the method for fabricating the same, which illustrate the method (Part 8).

FIGS. 16A-16C are sectional views of the semiconductor device according to the first embodiment of the present invention in the steps of the method for fabricating the same, which illustrate the method (Part 9).

FIGS. 17A-17C are sectional views of the semiconductor device according to the first embodiment of the present invention in the steps of the method for fabricating the same, which illustrate the method (Part 10).

FIGS. 18A-18C are sectional views of the semiconductor device according to the first embodiment of the present invention in the steps of the method for fabricating the same, which illustrate the method (Part 11).

FIGS. 19A-19D are transmission electron microscopic pictures showing the result of evaluating the method for fabricating the semiconductor device according to the first embodiment of the present invention.

FIG. 20 is a sectional view of the semiconductor device used in evaluating the method for fabricating the semiconductor device according to the first embodiment, which illustrate a structure thereof.

FIG. 21 is a graph of the result of evaluating the method for fabricating the semiconductor device according to the first embodiment of the present invention (Part 1).

FIG. 22 is a graph of the result of evaluating the method for fabricating the semiconductor device according to the first embodiment of the present invention (Part 2).

FIGS. 23A-23C are sectional views of the semiconductor device according to a second embodiment of the present invention in the steps of the method for fabricating the same, which illustrate the method.

### DETAILED DESCRIPTION OF THE INVENTION

[Principle of the Present Invention]

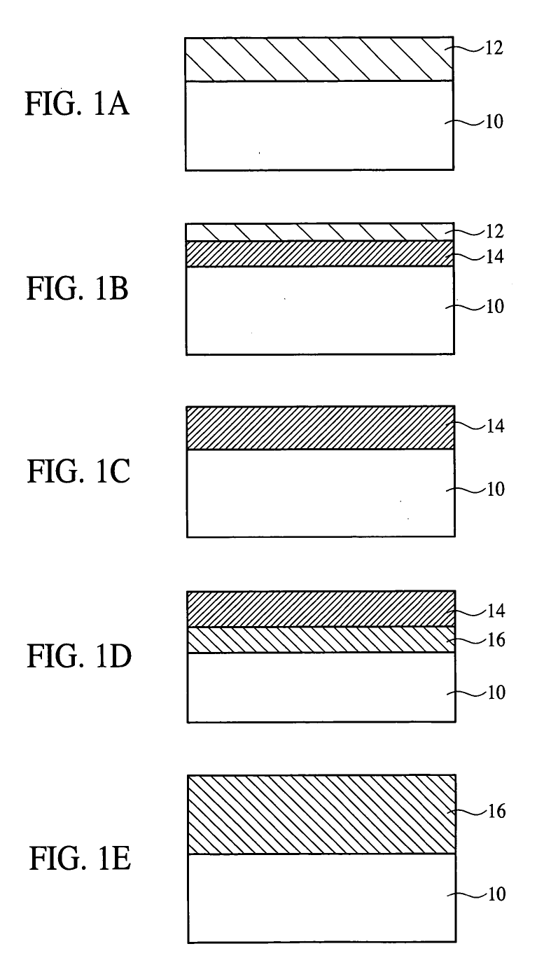

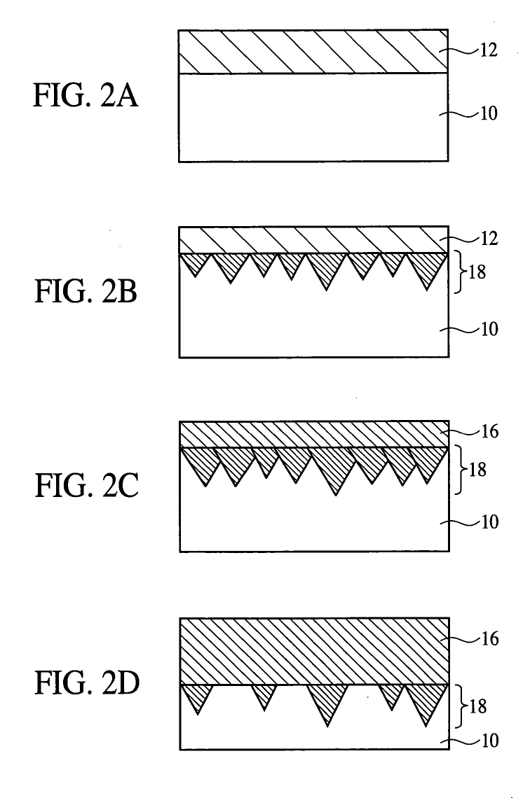

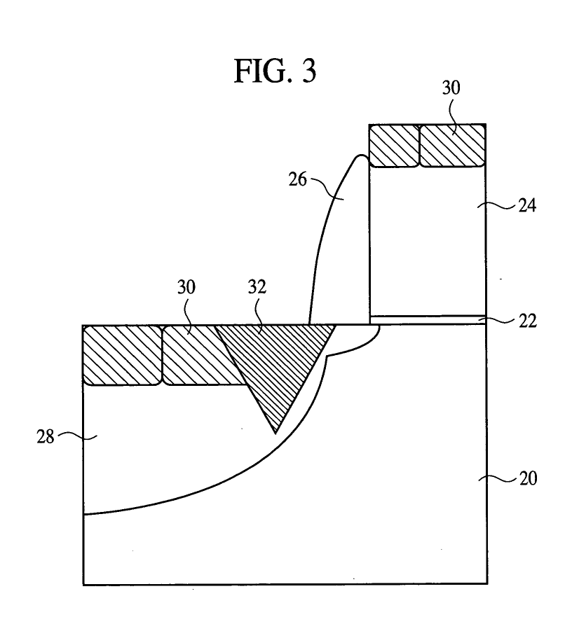

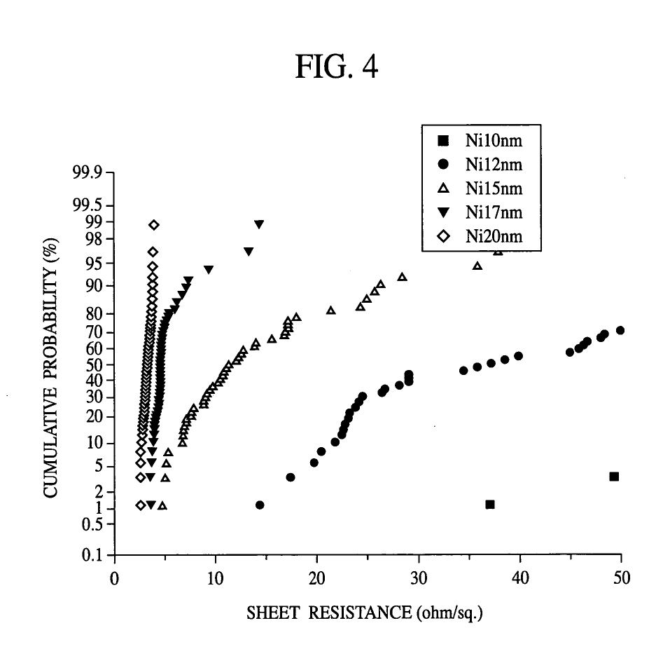

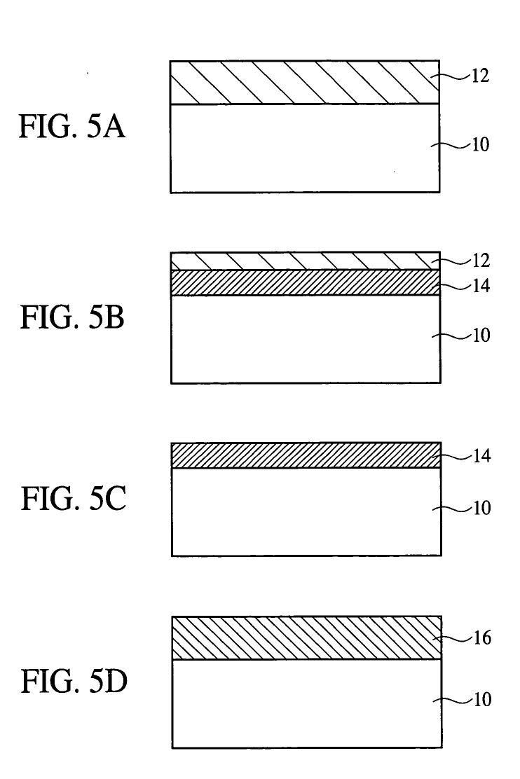

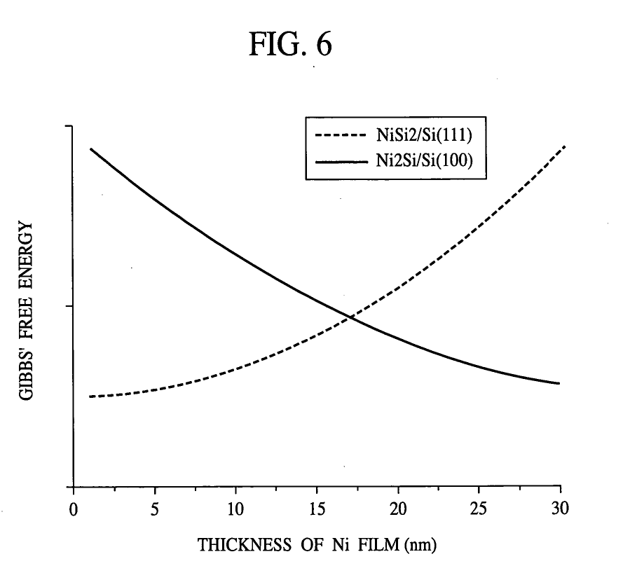

First, the principle of the present invention will be explained with reference to FIGS. 1A-1E, 2A-2D, 3, 4, 5A-5D and 6. FIGS. 1A-1E and 2A-2D are diagrammatic sectional views illustrating reaction models of the silicidation process for nickel silicide. FIG. 3 is a diagrammatic sectional view of a MOS transistor subjected to the salicide process using a relatively thin Ni film, which illustrates a structure of the MOS transistor. FIG. 4 is a graph of the results of an experiment in which the sheet resistance of source/drain diffused layers silicided using Ni film of different film thicknesses. FIGS. 5A-5D are diagrammatic sectional views illustrating the principle of the present invention. FIG. 6 is a graph schematically showing the relationship between the Gibbs' free energy of the system of a silicon substrate and nickel silicide film, and the film thickness of the Ni film.

The reaction models of silicidation process for forming nickel silicide with a silicon substrate and Ni film, which vary with film thicknesses of the Ni film have been so far reported. In the specification of the present application, “nickel silicide” widely means compounds of nickel and silicon, and when the compositions of the nickel silicide are clearly meant, “dinickel silicide (Ni₂Si)”, “nickel monosilicide (NiSi)” or “nickel disilicide (NiSi₂)” are respectively used.

First, for the silicidation process made on a sufficiently thick Ni film of an about 200 nm-thickness formed on a silicon substrate, the following reaction model has been reported (refer to F. d'Heurle, et al., J. Appl. Phys., vol. 55, pp. 4208-4218 (1984)).

When thermal processing is performed with an about 200 nm-thickness nickel (Ni) film 12 formed on a (111) or (100) silicon substrate 10 (see FIG. 1A), a dinickel silicide (Ni₂Si) film 14 is formed in the interface between the silicon substrate 10 and the Ni film 12 as illustrated in FIG. 1B. That is, the nickel silicide film 14 of Ni₂Si phase is formed in the interface between the silicon substrate 10 and the Ni film 12. The crystals of the Ni₂Si phase forming the nickel silicide film 14 has orthorhombic structure, in which the atomic composition ratio of Ni:Si is 2:1 and the lattice constant is a=0.499 nm, b=0.372 nm and c=0.703 nm (refer to F. d'Heurle, et al., J. Appl. Phys., vol. 55, pp. 4208-4218 (1984)). The Ni₂Si film 14 is formed because the Ni film 12 is thick, and the supply amount of the Ni is larger than that of the Si.

Then, as the thermal processing is being continued, as illustrated in FIG. 1C, the Ni₂Si film 14 goes on growing, and all the Ni becomes Ni₂Si. That is, on the silicon substrate 10, a nickel silicide film 14 of the Ni₂Si phase is formed.

Then, as the thermal processing is further being continued, as illustrated in FIG. 1D, a nickel monosilicide (NiSi) film 16 is formed in the interface between the silicon substrate 10 and the Ni₂Si film 14. That is, the nickel silicide film 16 of the NiSi phase is formed in the interface between the silicon substrate 10 and the Ni₂Si film 14. The crystals of the NiSi phase forming the nickel silicide film 16 is orthorhombic structure, in which the atomic composition ratio of Ni:Si is 1:1 and the lattice constant is a=0.5233 nm, b=0.3258 nm and c=0.5659 nm (refer to F. d'Heurle, et al., J. Appl. Phys., vol. 55, pp. 4208-4218 (1984)).

Then, as the thermal processing is further being continued, as illustrated in FIG. 1E, the NiSi film 16 goes on further growing, and even the Ni₂Si film 14 becomes the NiSi film. That is, on the silicon substrate 10, the nickel silicide film 16 of the nickel silicide alone of only the NiSi phase is formed.

As described above, in the silicidation process using a sufficiently thick Ni film of an about 200 nm-thickness, the reaction proceeds in the sequence of Ni₂Si and NiSi.

For the thermal processing made on a thin Ni film of a 12 nm-thickness formed on a silicon substrate, the result of the sectional observation by a transmission electron microscope has been reported (refer to V. Teodorescu, et al., J. Appl. Phys., vol. 90, pp. 167-174 (2001)). The reaction model made clear by the sectional observation by a transmission electron microscope is as follows.

When the thermal processing is performed for a 12 nm-thickness Ni film 12 formed on a (001) silicon substrate 10 (see FIG. 2A), as illustrated in FIG. 2B, nickel disilicide (NiSi₂) crystals 18 are formed inhomogeneously in the interface between the silicon substrate 10 and the Ni film 12. The crystals of NiSi₂ phase has the cubic structure, in which the atomic composition ratio of Ni:Si is 1:2 and the lattice constant is a=b=c=0.543 nm (refer to F. d'Heurle, et al., J. Appl. Phys., vol. 55, pp. 4208-4218 (1984)). The NiSi crystals 18 are formed in the early process of the reaction, as are not with the Ni film 12 formed thick, because the Ni film 12 is thin, and the supply amount of the Ni is smaller than that of the Si.

As the thermal processing is further being continued, as illustrated in FIG. 2C, the Ni film 12 on the NiSi₂ crystals becomes an NiSi film 16. At this time, the NiSi₂ crystals 18 are also gown in the silicon substrate 10. That is, on the silicon substrate 10, nickel silicide film in which the NiSi₂ phase and the NiSi phase are mixedly present is formed.

Then, as the thermal processing is being further continued, as illustrated in FIG. 2D, the NiSi film 16 goes on growing. At this time, below the NiSi film 16, the NiSi₂ crystals are formed inhomogeneously.

As described above, in the salicide process using relatively thin Ni film of an about 12 nm-thickness, the reaction proceeds in the sequence of NiSi₂ and NiSi, and the NiSi₂ crystals are formed inhomogenously below the NiSi film.

As described above, the process of silicidation reaction varies depending on film thicknesses of an Ni film formed on a silicon substrate.

In the silicidation using a relatively thick Ni film of an about 200 nm-thicknsess, as described above, the reaction proceeds in the sequence of Ni₂Si and NiSi, and the NiSi film can be formed homogeneously. The roughness of the interface between the silicon substrate and the NiSi film can be made small. However, with the recent increasing micronizatin of semiconductor devices, the height of the gate electrodes is below 100 nm including 100 nm, and the junction depth of the source/drain diffused layers is smaller. When the silicidation is made on a source/drain diffused layer of such small junction depth, using a thick Ni film, the NiSi film is often formed on the source/drain diffused layer too thick for the junction depth. The NiSi film formed on the source/drain diffused layer too thick for the junction depth increases the junction leak current.

However, when the silicidation is made, using a relatively thin Ni film of an about 12 nm-thickness, as described above, an NiSi film is formed, and NiSi₂ crystals are formed inhomogeneously below the NiSi film. The specific resistance of NiSi is 14 μΩ·cm, while the specific resistance of NiSi₂ is 34 μΩ·cm which is twice or more the specific resistance of the NiSi.

The NiSi₂ crystals of high resistance thus formed inhomogenous is a cause for increase of the roughness of the interface between the silicon substrate and the NiSi film, and increase of dispersions of the sheet resistance. This is also a cause for increase of the junction leak current.

FIG. 3 is a diagrammatic sectional view of a MOS transistor subjected to the salicide process using a relatively thin Ni film of an about 12 nm-thickness, which illustrates the structure thereof. As illustrated, a gate electrode 24 is formed on a silicon substrate 20 with a gate insulation film 22 formed therebetween. A sidewall insulation film 26 is formed on the side wall of the gate electrode 24. In the silicon substrate 20 on both sides of the gate electrode 24, a source/drain diffused layer 28 of the extension source/drain structure is formed. NiSi films 30 formed by the salicide process using a relatively thin Ni film are formed on the gate electrode 24 and the source/drain diffused layer 28. Because of the salicide process using a relatively thin Ni film, NiSi₂ crystals are formed inhomogeneously in the NiSi film 30 or below the NiSi film 30. That is, in the nickel silicide film, the NiSi phase and the NiSi₂ phase are mixed.

The junction depth of the source/drain diffused layer 28 is smaller at the part thereof near the end of the sidewall insulation film 26. Accordingly, as illustrated in FIG. 3, near the end of the sidewall insulation film 26, the NiSi₂ crystals 32 often reach a vicinity of the junction of the source/drain diffused layer 28. Such NiSi₂ crystals 32 are a cause for generating the junction leakage.

In semiconductor devices of the 90 nm-node technology, the junction depth of the source/drain diffused layers is below 80 nm including 80 nm. Accordingly, the film thickness of a metal silicide film to be formed as the source/drain electrodes on the source/drain diffused layers must be below 20 nm including 20 nm so as to sufficiently suppress the generation of the junction leakage. Thus, the film thickness of the Ni film used in the silicidation of the source/drain diffused layers is preferably below 13 nm including 13 nm. On the other hand, forming the Ni film thin forms the NiSi₂ crystals inhomogenesously, which is a cause for dispersions of the sheet resistance and the junction leakage. As described above, in performing the silicidation using Ni film for micronized MOS transistors, the conventional processes cannot avoid forming the Ni film thin, which will make it difficult to avoid the formation of NiSi₂ crystals which cause deterioration of the transistor characteristics.

The inventor of the present application has made an experiment of measuring the sheet resistance of a source/drain diffused layer silicided using Ni films of different thicknesses so as to make clear the film thickness of the Ni film which permits the silicidation to be performed, suppressing the generation of the NiSi₂ crystals. In the experiment, the surface of a 0.14 μm-width boron-doped source/drain diffused layer was silicided by using a 10 nm-thickness, a 12 nm-thickness, a 15 nm-thickness, a 17 nm-thickness and a 20 nm-thickness Ni films. For each film thickness, the sheet resistance was measured on a plurality of samples, and cumulative probabilities of the samples were plotted. FIG. 4 is a graph of the experimental result. The sheet resistances of the source/drain diffused layer are taken on the horizontal axis, and the cumulative probabilities are taken on the vertical axis. The ▪ marked plots indicate the measured results of the 10 nm-thickness Ni film, the ● marked plots indicate the measured results of the 12 nm-thickness Ni film, the Δ marked plots indicate the measured results of the 15 nm-thickness Ni film, the ▾ marked plots indicate the measured results of the 17 nm-thickness Ni film, and the ⋄ marked plots indicate the measured results of the 20 nm-thickness Ni film.

As evident from the experimental result shown in FIG. 4, the dispersions of the sheet resistances in the silicidation with the 17 nm-thickness Ni film and the 20 nm-thickness Ni film are much smaller than those in the silicidation with the 10 nm-thickness Ni film, the 12 nm-thickness Ni film and the 15 nm-thickness Ni film. Based on this result, it can be said that when the film thickness of the Ni film is above 17 nm including 17 nm, the formation of the NiSi₂ crystals was suppressed. That is, it is considered that in this case, the silicidation of the reaction model illustrated in FIG. 1 took place. In addition, when the film thickness of the Ni film is above 17 nm including 17 nm, the aggregation of the silicide was also suppressed.

On the other hand, when the film thickness of the Ni film is below 17 nm including 17 nm, the dispersions of the sheet resistance of the silicided source/drain diffused layer were conspicuous. Based on this result, when the film thickness of the Ni film is below 17 nm including 17 nm, it can be said the NiSi₂ crystals were formed. That is, it is considered that in this case, the silicidation of the reaction model illustrated in FIG. 2 took place.

Here, the film thickness of the NiSi film formed with the Ni film of a film thickness of above 20 nm including 20 nm is above 30 nm including 30 nm. Accordingly, when the surface of the gate electrode and the surface of the source/drain diffused layers are silicided simply with an Ni film of a film thickness of above 20 nm including 20 nm, the formation of the NiSi₂ crystals is suppressed, but there is a risk that the junction leak current may be increased.

The inventor of the present application has made earnest studies and have got an idea that, in the following way, the NiSi film of a required film thickness can be formed while the formation of the NiSi₂ crystals of high resistance can be suppressed. The silicidation process of the present invention will be explained with reference to FIGS. 5A-5D.

First, as illustrated in FIG. 5A, an Ni film 12 of, e.g., a 20 m-thickness is formed on a silicon substrate 10. The film thickness of the Ni film 12 is, e.g., above 17 nm including 17 nm. However, it is preferable to set the film thickness of the Ni film 12 at below 200 nm including 200 nm at most because, as will be described later, the part of the Ni film 12, which has not reacted with the Si, must be removed without failure after the silicidation.

Then, as the first thermal processing, RTA (Rapid Thermal Annealing), for example is performed at 270° C. for 30 seconds, whereby as illustrated in FIG. 5B, the Ni in a part of the Ni film 12 on the side of the lower side and the Si in a part of the silicon substrate 10 on the upper side are reacted with each other to form an Ni₂Si film 14. That is, the nickel silicide film 14 formed of nickel silicide alone of the Ni₂Si phase alone is formed in the interface between the silicon substrate 10 and the Ni film 12. The film thickness of the part of the Ni film 12 on the lower side, which is reacted with Si, is, e.g., 10 nm. The thermal processing temperature of the first thermal processing is, e.g., 200-400° C. The thermal processing time is, e.g., 10 seconds-60 minutes.

Then, as illustrated in FIG. 5C, the part of the Ni film 12, which has not reacted with the Si is selectively etched off. The etching solution is, e.g., sulfuric acid/hydrogen peroxide mixture mixing sulfuric acid and hydrogen peroxide in a ratio of 3:1. The etching time is set in accordance with a film thickness of the part of the Ni film 12, which has not reacted with the Si, etc. For example, the etching time is 1-3 minutes.

Then, the second thermal processing is performed by, e.g., RTA at 500° C. for 30 seconds. Thus, as illustrated in FIG. 5D, the Ni₂Si in the Ni₂Si film 14 and the Si in a part of the silicon substrate 10 on the upper side are reacted with each other to form an NiSi film 16. That is, a nickel silicide film 16 of the nickel silicide alone of the NiSi phase alone is formed on the silicon substrate 10. The thermal processing temperature of the second thermal processing is substantially equal to or higher than that of the first thermal processing. Specifically, the thermal processing temperature is, e.g., 350-650° C. The thermal processing time is, e.g., 10 seconds-60 seconds.

As described above, in the silicidation of the present invention, a part of the relatively thick Ni film 12 on the lower side and a part of the silicon substrate 10 on the upper side are reacted with each other by the fist thermal processing. Because the Ni film 12 is relatively thick, in the first thermal processing, the Ni₂Si film 14 can be formed while the formation of NiSi₂ crystals is suppressed. Then, the part of the Ni film 12, which has not reacted with the Si, is etched off, and then the Ni₂Si film 14 and a part of the silicon substrate 10 on the upper side are reacted with each other by the fist second processing to form the NiSi film 16, whereby the NiSi film 16 is prevented from being formed too thick. The film thickness of the NiSi film 16 can be controlled by suitably setting conditions, such as the thermal processing temperatures and the thermal processing times of the first and the second thermal processing, etc.

Thus, the NiSi film 16 of good quality and low resistance can be formed in a required film thickness on the silicon substrate 10 while the formation of the NiSi₂ film of high resistance is suppressed, whereby the roughness of the interface between the silicon substrate 10 and the NiSi film 16 can be made small. Thus, when the surface of the gate electrode and the surface of the source/drain diffused layers are silicided, dispersions of the sheet resistance can be suppressed. The junction leak current can be suppressed.

It is preferable to set the film thickness of the Ni film at above 17 nm including 17 nm so that the Ni₂Si film is formed by the first thermal processing while the formation of the NiSi₂ film is suppressed. The reason for this will be described below.

FIG. 6 is a graph schematically showing the relationships between the Gibbs' free energy of the system of a silicon substrate and a nickel silicide film, and the film thickness of an Ni film used in the silicidation. In the graph, the dotted curve indicates the relationships between the Gibbs' free energy of the system of a silicon substrate and an NiSi₂ film, and the film thickness of the Ni film used in the silicidation. In the graph, the solid curve indicates the relationships between the Gibbs' free energy of the system of a silicon substrate and an Ni₂Si film, and the film thickness of the Ni film used in the silicidation.

As seen in the graph of FIG. 6, with the 17 nm-film thickness of the Ni film as the border, when the film thickness of the Ni film is smaller than the bordering film thickness, the system of the silicon substrate and the NiSi₂ film will have lower Gibbs' free energy than the system of the silicon substrate and the Ni₂Si film. Accordingly, in this case, it is considered that the NiSi₂ film is stably formed.

On the other hand, with the 17 nm-film thickness of the Ni film as the border, when the film thickness of the Ni film is larger than the bordering film thickness, the system of the silicon substrate and the Ni₂Si film will have higher Gibbs' free energy than the system of the silicon substrate and the NiSi₂ film. Accordingly, in this case, it is considered that the Ni₂Si film is stably formed. That is, the film thickness of the Ni film is set at above 17 nm including 17 nm, whereby the formation of the NiSi₂ film could be sufficiently suppressed.

As described above, the film thickness of an Ni film is set above 17 nm including 17 nm, more preferably above 20 nm including 20 nm, whereby an Ni₂Si film could be formed while the formation of NiSi₂ film is suppressed. This is endorsed by the measured result of the sheet resistance of the source/drain diffused layers shown in FIG. 4.

### A First Embodiment

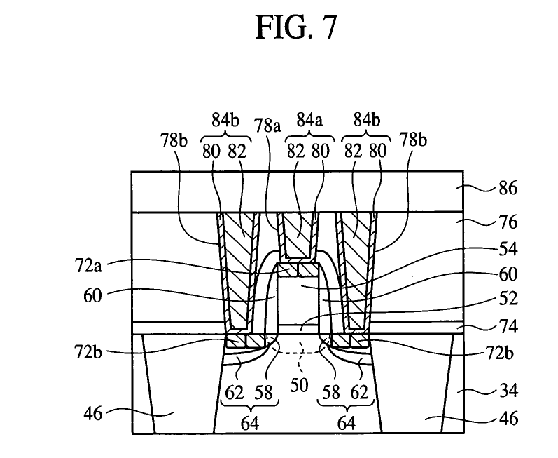

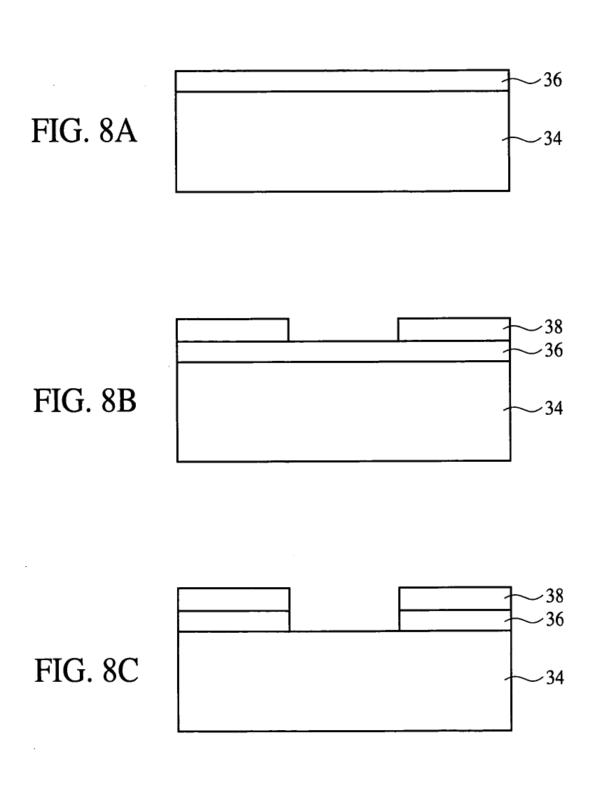

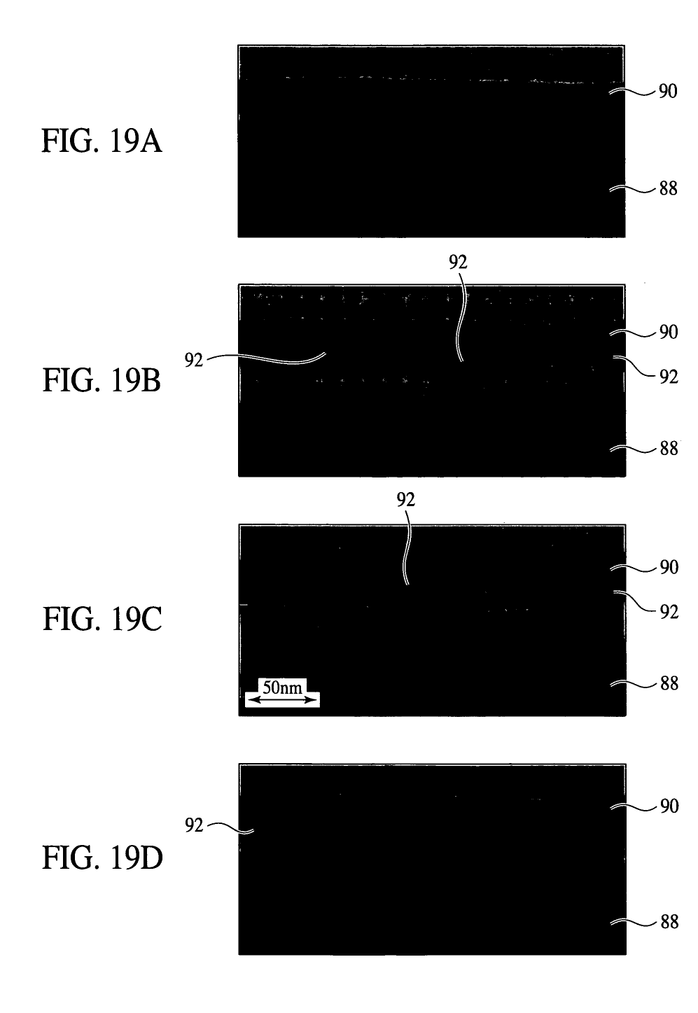

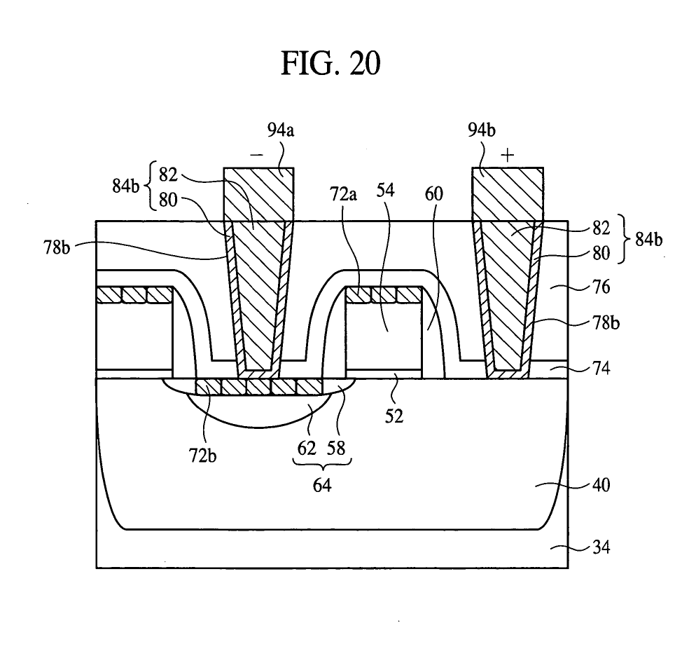

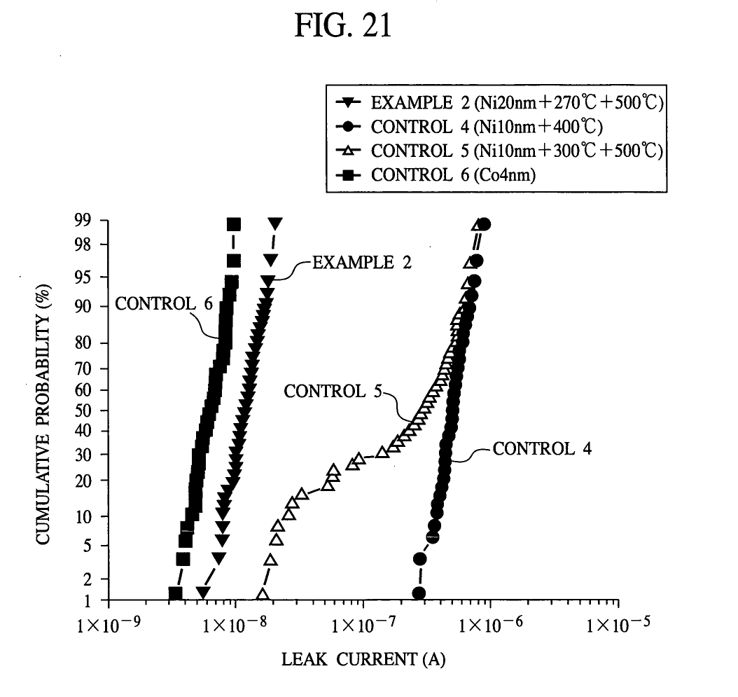

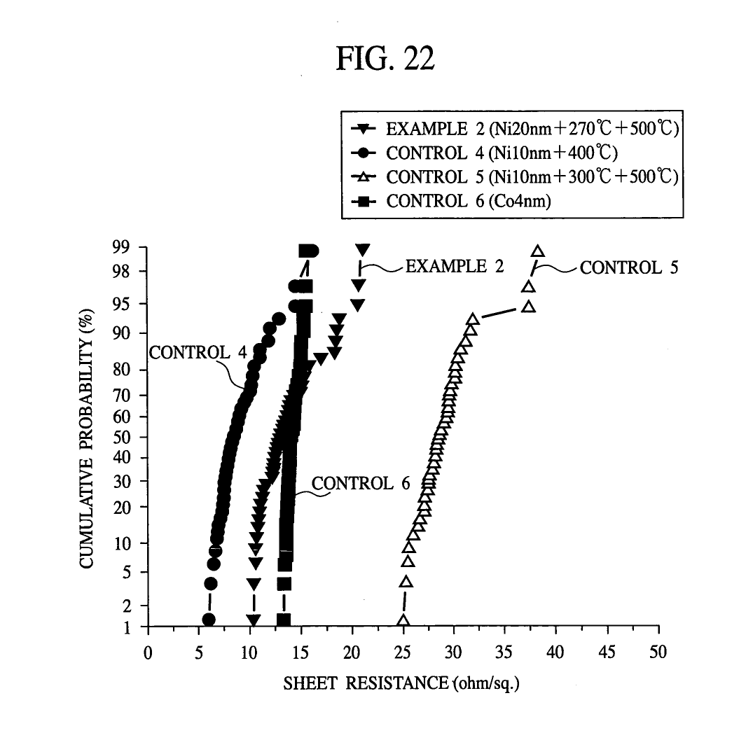

The semiconductor device according to a first embodiment of the present invention and the method for fabricating the same will be explained with reference to FIGS. 7 to 22. FIG. 7 is a sectional view of the semiconductor device according to the present embodiment. FIGS. 8A-8C to 18A-18C are sectional views of the semiconductor device according to the present embodiment in the steps of the method for fabricating the semiconductor device, which illustrate the method. FIGS. 19A-19D are transmission electron microscopic pictures showing the results of evaluating the method for fabricating the semiconductor device according to the present embodiment. FIG. 20 is a sectional view of the semiconductor device used in evaluating the method for fabricating the semiconductor device according to the present embodiment, which shows the structure thereof. FIGS. 21 and 22 are graphs of the results of evaluating the method for fabricating the semiconductor device according to the present embodiment.

First, the structure of the semiconductor device according to the present embodiment will be explained with reference to FIG. 7.

Device isolation regions 46 for defining a device region are formed in a silicon substrate 34. A well (not shown) is formed in the silicon substrate 34 with the device isolation regions 46 formed in.

On the silicon substrate 34 with the well formed in, a gate electrode 54 of polysilicon film is formed with a gate insulation film 52 of silicon oxide film formed therebetween. On the gate electrode 54, a nickel silicide film 72a of NiSi alone is formed. That is, the nickel silicide film 72a is formed of nickel silicide alone of the NiSi phase alone. The film thickness of the nickel silicide film 72a is, e.g., below 20 nm including 20 nm.

Sidewall insulation films 60 are formed on the side walls of the gate electrode 54 with the nickel silicide film 72a formed on.

A channel doped layer 50 is formed in the silicon substrate 34 below the gate electrode 54. In the silicon substrate 34 on both sides of the gate electrode 54, source/drain diffused layers 64 including a shallow impurity diffused region 58 forming the extension region of the extension source/drain structure, and a deep impurity diffused region 62 are formed. Nickel silicide films 72b of NiSi alone are formed on the source/drain diffused layers 64. That is, the nickel silicide film 72b is formed of nickel silicide alone of the NiSi phase alone. The film thickness of the nickel silicide film 72b is, e.g., below 20 nm including 20 nm.

Thus, a MOS transistor including the gate electrode 54 and the source/drain diffused layers 62 is formed on the silicon substrate 34.

A silicon nitride film 74 is formed on the silicon substrate 34 with the MOS transistor formed on. A silicon oxide film 76 is formed on the silicon nitride film 74.

A contact hole 78a is formed in the silicon oxide film 76 and the silicon nitride film 74 down to the nickel silicide film 72a on the gate electrode 54. Contact holes 78b are formed in the silicon oxide film 76 and the silicon nitride film 74 down to the nickel silicide films 72b on the source/drain diffused layers 64.

Contact plugs 84a, 84b of a barrier metal 80 and a tungsten film 82 are buried respectively in the contact holes 78a, 78b.

An inter-layer insulation film 86 is formed on the silicon oxide film 76 with the contact plugs 84a, 84b buried in.

Thus, the semiconductor device according to the present embodiment is constituted.

The semiconductor device according to the present embodiment is characterized mainly in that the nickel silicide films 72a, 72b formed respectively on the gate electrode 54 and on the source/drain diffused layers 64 are formed of nickel silicide alone of the NiSi phase alone.

That is, in the semiconductor device according to the present embodiment, no NiSi₂ crystals are formed in the nickel silicide films 72a, 72b. NiSi₂ crystals are formed neither in the interface between the nickel silicide film 72a and the gate electrode 54 nor the interface between the nickel silicide film 72b and the silicon substrate 34.

As described above, because the nickel silicide films 72a, 72b are formed of nickel silicide alone of the NiSi phase alone, the roughness of the interface between the NiSi film 72a and the gate electrode 54 and the interface between the NiSi film 72b and the source/drain diffused layers 64 can be made small, whereby dispersions of the sheet resistance of the surface of the gate electrode 54 and the source/drain diffused layer 64 can be suppressed.

The film thickness of the nickel silicide film 72b is as thin as, e.g., below 20 nm including 20 nm, and furthermore, no NiSi₂ crystals, which arrive at a vicinity of the junction of the source/drain diffused layer 64, causing the junction leakage, are formed, whereby even when the depth of the junction of the source/drain diffused layer 64 is small, the junction leak current can be suppressed.

Next, the method for fabricating the semiconductor device according to the present embodiment will be explained with reference to FIGS. 8A-8C to 18A-18C.

First, the surface of the silicon substrate 34 is cleaned with, e.g., ammonia/hydrogen peroxide mixture. The silicon substrate 34 is, e.g., a p type (100) silicon substrate.

Then, a silicon oxide film 36 of, e.g., a 50 nm-thickness is formed on the silicon substrate 34 by, e.g., thermal oxidation (see FIG. 8A).

Next, a photoresist film 38 is formed by, e.g., spin coating. Then, the photoresist film 38 is patterned by photolithograpy. Thus, a photoresist mask 38 for patterning the silicon oxide film 36 is formed (see FIG. 8B).

Then, with the photoresist film 38 as the mask, the silicon oxide film 36 is etched (see FIG. 8C).

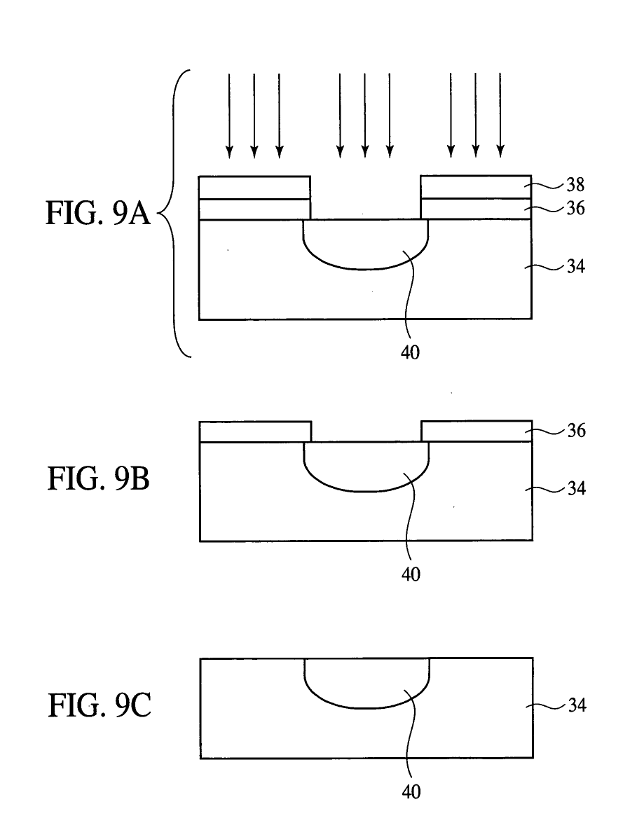

Then, with the photoresist film 38 and the silicon oxide film 36 as the mask, a dopant impurity is implanted into the silicon substrate 34 by, e.g., ion implantation. Thus, a well 40 of a required conduction type is formed (see FIG. 9A). When a p type well for an NMOS transistor to be formed in is formed, boron, for example, as a p type dopnat impurity is used, and conditions for the ion implantation are a 120 keV acceleration voltage and a 1×10¹³ cm⁻² dose. When an n type well for a PMOS transistor to be formed in is formed, phosphorus, for example, as an n type dopant impurity is used, and conditions for the ion implantation are, e.g., a 300 keV acceleration energy and a 1×10¹³ cm⁻² dose.

After the well 40 has been formed, the photoresist film 38 is removed (see FIG. 9B). Then, the silicon oxide film 36 is etched off (see FIG. 9C).

Next, the device isolation regions for defining device regions are formed by, e.g., STI (Shallow Trench Isolation) in the following way.

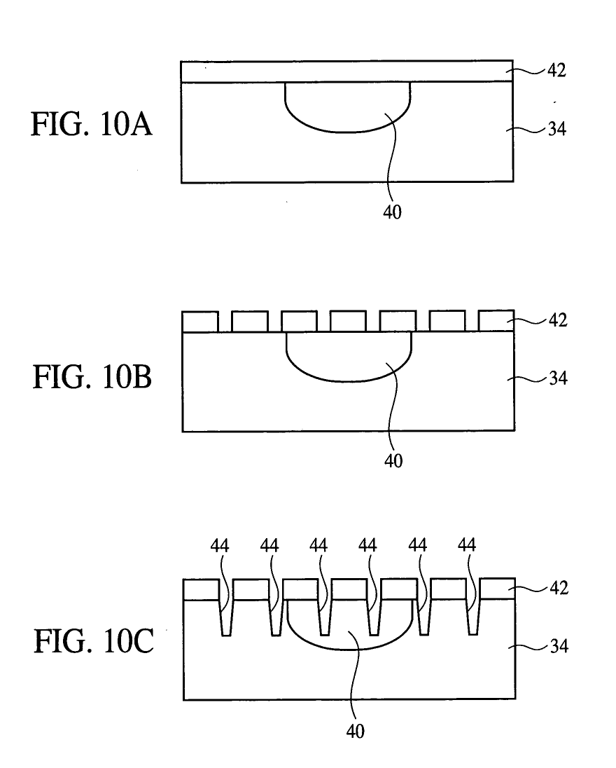

First, a silicon nitride film 42 of, e.g., a 50 nm-thickness is formed on the silicon substrate 34 by, e.g., CVD (Chemical Vapor Deposition) (see FIG. 10A).

Then, the silicon nitride film 42 is patterned by photolithography and dry etching. Thus, a hard mask 42 for forming trenches for a silicon oxide film to be buried in is formed (see FIG. 10B).

Then, with the silicon nitride film 42 as the mask, the silicon substrate 34 is etched. Thus, the trenches 44 are formed in the silicon substrate 34 (see FIG. 10C).

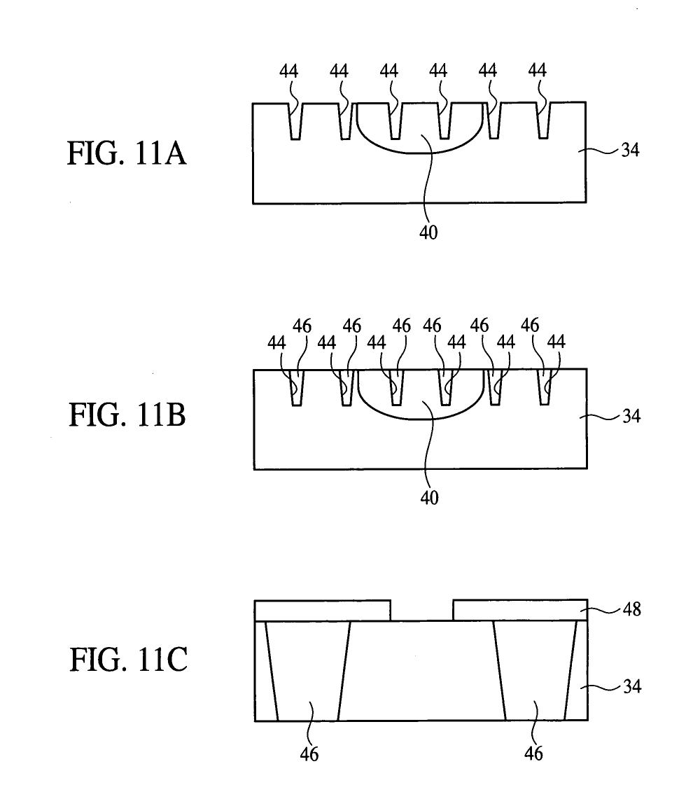

After the trenches 44 have been formed, the silicon nitride film 42 used as the mask is removed by, wet etching (see FIG. 11A).

Next, a silicon oxide film of, e.g., a 300 nm-thickness is formed by, e.g., CVD on the silicon substrate 34 with the trenches 44 formed in.

Next, the silicon oxide film is polished by, e.g., CMP (Chemical Mechanical Polishing) until the surface of the silicon substrate 34 is exposed to thereby remove the silicon oxide film on the silicon substrate 34.

Thus, the device isolation regions 46 of the silicon oxide film buried in the trenches 44 are formed (see FIG. 11B). The device isolation regions 46 define the device regions.

Next, a photoresist film 48 is formed by, e.g., spin coating. Then, the photoresist film 48 is patterned by photolithography. Thus, a photoresist mask 48 for forming the channel doped layer is formed (see FIG. 1C). In the drawings following the drawing of FIG. 1C, a device region for a MOS transistor to be formed in is enlarged.

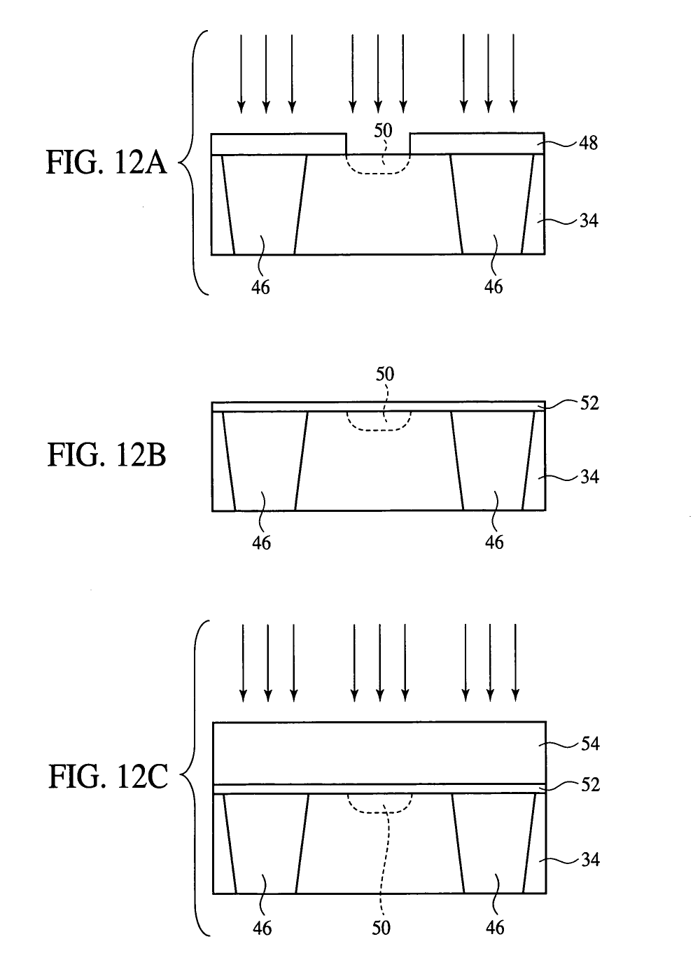

Then, with the photoresist film 48 as the mask, a dopant impurity is implanted into the silicon substrate 34 by, e.g., ion implantation. Thus, the channel doped layer 50 is formed in the silicon substrate 34 (see FIG. 12A). When an NMOS transistor is formed, boron, for example, as the p type dopant impurity is used, and conditions for the ion implantation are, e.g., a 15 keV acceleration energy and a 1×10¹³ cm⁻² dose. When a PMOS transistor is formed, arsenic, for example, as the n type dopant impurity is used, and conditions for the ion implantation are, e.g., a 80 keV acceleration energy and a 1×10¹³ cm⁻² dose.

After the channel doped layer 50 has been formed, the photoresist film 48 used as the mask is removed.

Then, the dopant impurity in the channel doped layer 50 is activated by thermal processing of, e.g., 950° C. and 10 seconds.

Next, the gate insulation film 52 of a silicon oxide film of, e.g., a 2 nm-thickness is formed on the silicon substrate 34 by, e.g., thermal oxidation (FIG. 12B). The gate insulation film 52 is formed of silicon oxide film but may not be formed essentially of silicon oxide film. Any other insulation film can be suitably used.

Next, a polysilicon film 54 of, e.g., a 100 nm-thickness is formed on the entire surface by, e.g., CVD.

Next, a dopant impurity is implanted into the polysilicon film 54 by, e.g., ion implantation (see FIG. 12C). When an NMOS transistor is formed, phosphorus, for example, is used as the n type dopant impurity, and conditions for the ion implantation are, e.g., a 10 keV acceleration energy and a 1×10¹⁶ cm⁻² dose. When a PMOS transistor is formed, boron, for example, is used as the p type dopant impurity, and conditions for the ion implantation are, e.g., 5 keV and a 5×10¹⁵ cm².

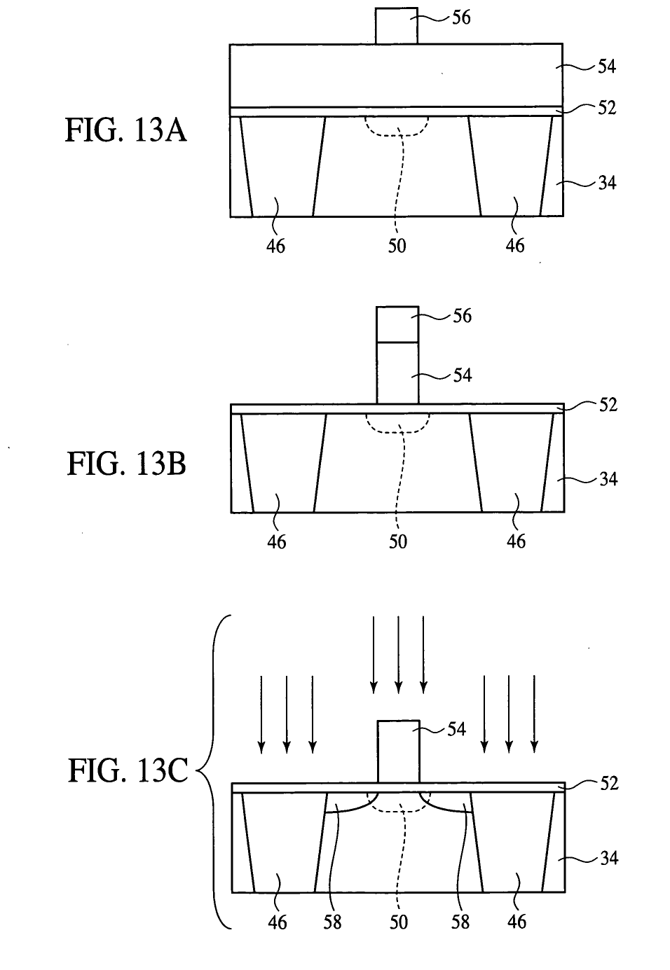

Then, a photoresist film 56 is formed by, e.g., spin coating. Then, the photoresist film 56 is patterned by photolithography. Thus, a photoresist mask 56 for patterning the polysilicon silicon film 54 is formed (see FIG. 13A).

Next, with the photoresist film 56 as the mask, the polysilicon film 54 is dry etched. Thus, the gate electrode 54 is formed of the polysilicon film (see FIG. 13B).

After the gate electrode 54 has been formed, the photoresist film 56 used as the mask is removed.

Then, with the gate electrode 54 as the mask, a dopant impurity is implanted into the silicon substrate 34 on both sides of the gate electrode 54 by, e.g., ion implantation. When an NMOS transistor is formed, arsenic, for example is used as the n type dopant impurity, and conditions for the ion implantation are, e.g., a 1 keV acceleration energy and a 1×10¹⁵ cm⁻² dose. When a PMOS transistor is formed, boron, for example is used as the p type dopant impurity, and conditions for the ion implantation are, e.g., a 0.5 keV acceleration energy and a 1×10¹⁵ cm⁻² dose. Thus, the shallow impurity diffused regions 58 forming the extension regions of the extension source/drain structure are formed (see FIG. 13C).

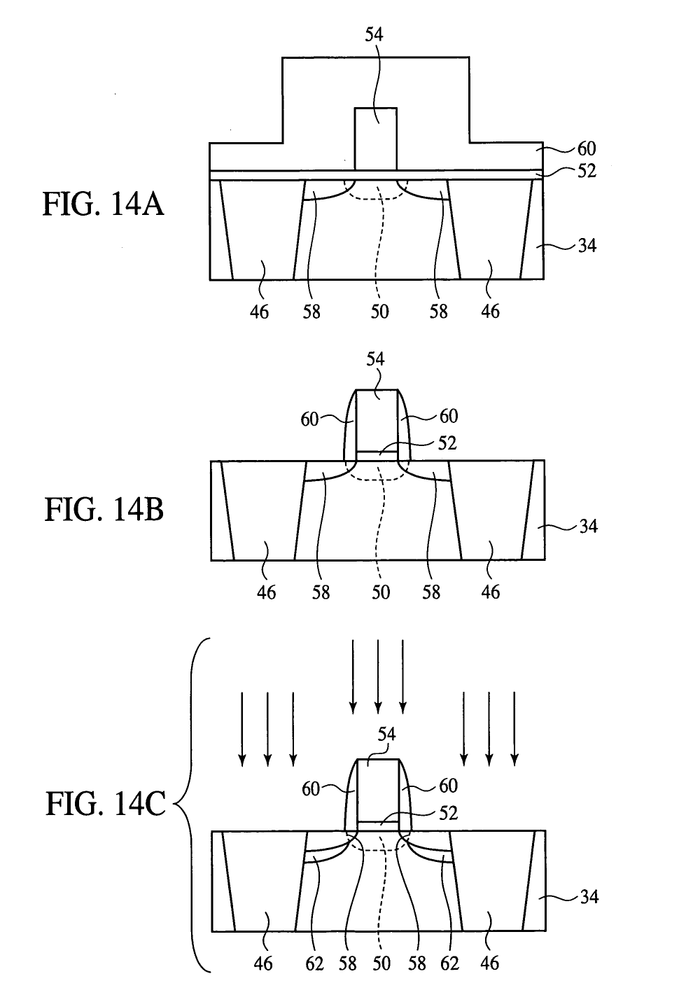

Next, a silicon oxide film 60 of, e.g., a 100 nm-thickness is formed on the entire surface by, e.g., CVD (see FIG. 14A).

Then, the silicon oxide film 60 is anisotropically etched by, e.g., RIE (Reactive Ion etching). Thus, the sidewall insulation films 60 are formed of the silicon oxide film on the side walls of the gate electrode 54 (see FIG. 14B). The sidewall insulation film 60 is formed of silicon oxide film here but may not be formed essentially of silicon oxide film. Any other insulation film can be suitably used.

Next, with the gate electrode 54 and the sidewall insulation film 60 as the mask, a dopant impurity is implanted into the silicon substrate 34 on both sides of the gate electrode 54 and the sidewall insulation films 60. When an NMOS transistor is formed, phosphorus, for example, is used as the n type dopant impurity, and conditions for the ion implantation are, e.g., an 8 keV acceleration energy and a 1×10¹⁶ cm⁻² dose. When a PMOS transistor is formed, boron, for example is used as the p type dopant impurity, and conditions for the ion implantation are, e.g., a 5 keV acceleration energy and a 5×10¹⁵ cm⁻² dose. Thus, the impurity diffused regions 62 forming the deep regions of the source/drain diffused layers are formed (see FIG. 14C).

Next, the dopant impurities implanted in the impurity diffused regions 58, 62 are activated by prescribed thermal processing.

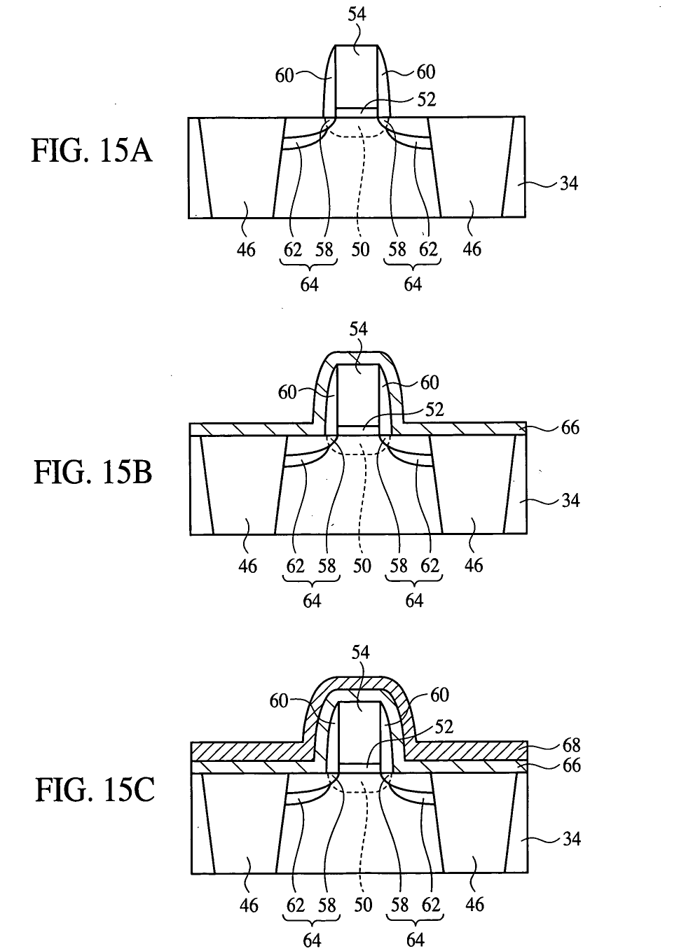

Thus, the source/drain diffused layers 64 formed of the extension region, i.e., the shallow impurity diffused region 58, and the deep impurity diffused region 62 are formed in the silicon substrate 34 on both sides of the gate electrode 54 (see FIG. 15A).

Next, native oxide film formed on the surface of the gate electrode 54 and the surface of the source/drain diffused layers 64 are removed by the processing with, e.g., hydrofluoric acid.

Then, an Ni film 66 of, e.g., a 20 nm-thickness is formed on the entire surface by sputtering with, e.g., an Ni target (see FIG. 15B). The film thickness of the Ni film 66 is, e.g., above 17 nm including 17 nm. As will be described later, it is preferable that the film thickness of the Ni film 66 is below 200 nm including 200 nm because after the first thermal processing, the part of the Ni film 66, which has not reacted with the Si must be removed.

Then, a protection film 68 of a titanium nitride (TiN) film of, e.g., a 5-50 nm-thickness is formed on the Ni film 66 by, e.g., PVD (Physical Vapor Deposition) (see FIG. 15C). The protection film 68 may not be formed of essentially titanium nitride. The protection film 68 may be, e.g., a titanium (Ti) film of a 5-30 nm-thickness.

The protection film 68 can prevent the nickel film 66, and the nickel silicide film which will be formed later from being oxidized.

When the substrate with the Ni film 66 formed on is mounted with the Ni film 66 exposed on a cassette for transporting substrates or loaded in the furnace of an RTA apparatus or the chamber of a film deposition apparatus, the cassette, the furnace or the chamber are contaminated with the Ni, and particles of the Ni often adhere to other substrates which are later mounted on the cassette or loaded in the furnace of the RTA apparatus or the chamber of the film deposition apparatus. The protection film 68 formed on the Ni film 66 can prevent the secondary contamination with the Ni.

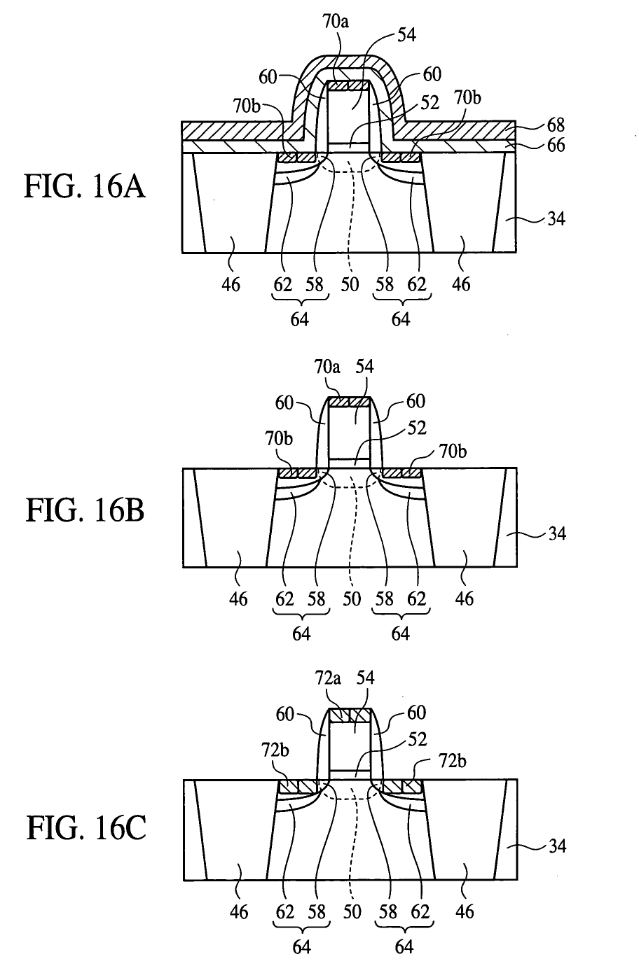

Then, the first thermal processing for the silicidation is performed by, e.g., RTA at, e.g., 270° C. and for 30 seconds. Thus, the Ni in a part of the Ni film 66 on the lower side and the Si in a part of the gate electrode 54 on the upper side are reacted with each other, and the Ni in a part of the Ni film 66 on the lower side and the Si in a part of the source/drain diffused layers 64 on the upper side are reacted with each other. Thus, the Ni₂Si film 70a is formed on the gate electrode 54 and the Ni₂Si films 70b are formed on the source/drain diffused layers 64 (see FIG. 16A). That is, the nickel silicide films 70a, 70b of nickel silicide alone of the Ni₂Si phase alone are formed in the interface between the gate electrode 54 and the Ni film 66 and in the interface between the source/drain diffused layers 64 and the Ni film 66.

Then, the protection film 68 and the part of the Ni film 66, which have not reacted with the Si are respectively selectively removed by wet etching (see FIG. 16B). The etching solution is, e.g., sulfuric acid/hydrogen peroxide mixture mixing, e.g., sulfuric acid and hydrogen peroxide in a 3:1 ratio. The etching time is, e.g., 20 minutes.

Next, as the second thermal processing for the silicidation, thermal processing is performed by, e.g., RTA at, e.g., 500° C. and for 30 seconds. Thus, the Ni₂Si in the Ni₂Si film 70a and the Si in a part of the gate electrode 54 on the upper side are reacted with each other, and the Ni₂Si in the Ni₂Si film 70b and the Si in a part of the source/drain diffused layers 64 on the upper side are reacted with each other. Thus, the NiSi film 72a is formed on the gate electrode 54, and the NiSi film 72b is formed on the source/drain diffused layers 64 (see FIG. 16C). That is, the nickel silicide films 72a, 72b of nickel silicide alone of the NiSi phase alone is formed on the gate electrode 54 and the source/drain diffused layers 64.

Thus, by the salicide process, the NiSi films 72a is formed on the gate electrode 54 and the NiSi films 72b are formed on the source/drain diffused layers 64. The NiSi films 72a, 72b can be formed in a required film thickness by suitably setting the film thickness of the Ni film 66 and conditions for the first and the second thermal processing. For example, the NiSi films 72a, 72b can be formed in a film thickness of below 20 nm including 20 nm.

As described above, the method for fabricating the semiconductor device according to the present embodiment is characterized mainly in that after the Ni film 66 has been formed relatively thick, by the first thermal processing, the Si in parts of the gate electrode 54 and the source/drain diffused layers 64 on the upper side is reacted with the Ni in a part of the Ni film 66 on the lower side to thereby form the Ni₂Si film 70a, 70b on the gate electrode 54 and the source/drain diffused layers 64, then a part of the Ni film 66, which has not reacted with the Si is selectively removed, and then by the second thermal processing, the Si in parts of the gate electrode 54 and the source/drain diffused layers 64 is reacted with the Ni₂Si in the Ni₂Si film 70a, 70b to thereby form the NiSi films 72a, 72b on the gate electrode 54 and the on the source/drain diffused layers 64.

By the first thermal processing, the Si in parts of the gate electrode 54 and the source/drain diffused layers 64 on the upper sides thereof is respectively reacted with the Ni in a part of the relatively thick Ni film 66 on the lower side, whereby in the first thermal processing, the Ni₂Si films 70a, 70b can be formed while the formation of NiSi₂ crystals is suppressed. Then after the part of the Ni film 66, which has not reacted with the Si, is selectively removed, and then by the second thermal processing, the Si in parts of the gate electrode 54 and the source/drain diffused layer 64 on the upper sides thereof is reacted respectively with the Ni₂Si in the Ni₂Si films 70a, 70b to thereby form the NiSi film 70a, 70b. Thus, the NiSi film 72a, 72b are prevented from being formed too thick. The film thickness of the NiSi film 72a, 72b can be controlled by suitably setting conditions, such as the thermal processing temperature, thermal processing time of the first and the second thermal processing, etc.

Thus, the NiSi films 72a, 72b of good quality can be formed in a required film thickness can be formed on the gate electrode 54 and the source/drain diffused layers 64 while the formation of the NiSi₂ crystals of high resistance is suppressed, whereby the roughness in the interface between the NiSi film 72a and the gate electrode 54 and in the interface between the NiSi film 72b and the source/drain diffused layers 64 can be made small. The dispersion of the sheet resistance of the surface of the gate electrode 54 and the surface of the source/drain diffused layers 64 can be suppressed. Also, the junction leak current can be suppressed.

Then, a silicon nitride film 74 of, e.g., a 50 nm-thickness is formed on the entire surface by, e.g., plasma CVD. The deposition temperature of the silicon nitride film 74 is, e.g., 500° C. The steps following the salicide process are performed at temperature of, e.g. below 500° C. including 500° C. so as to suppress the aggregation of the NiSi films 72a, 72b.

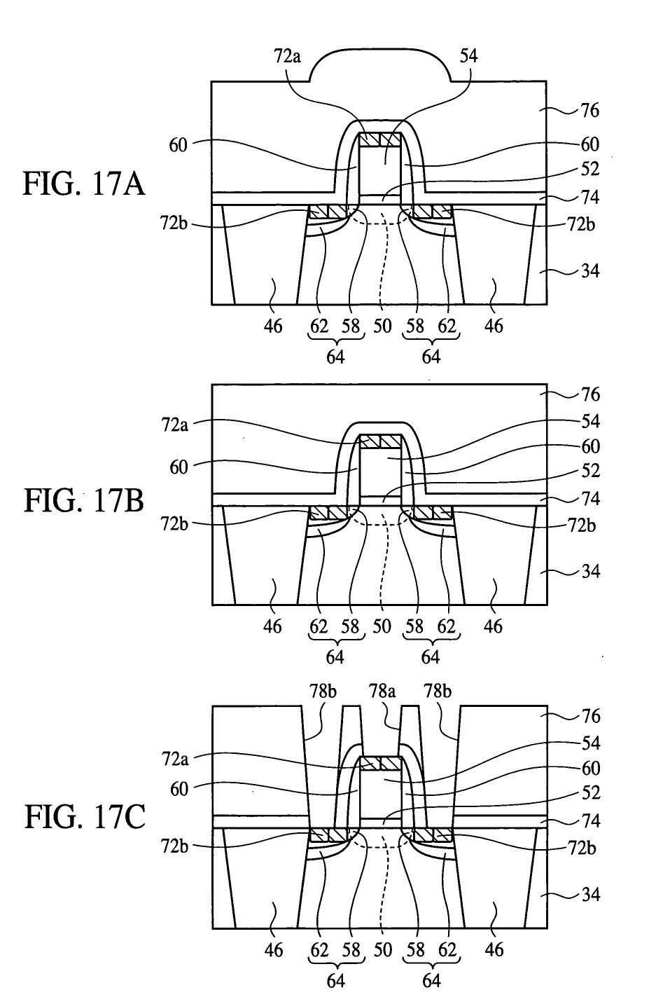

Next, a silicon oxide film 76 of, e.g., a 600 nm-thickness is formed on the silicon nitride film 74 by, e.g., plasma CVD (see FIG. 17A).

Then, the silicon oxide film 76 is flattened by, e.g., CMP (see FIG. 17B).

Next, by photolithography and dry etching, a contact hole 78a and contact holes 78b are formed in the silicon oxide film 76 and the silicon nitride film 74 respectively down to the NiSi film 72a and the NiSi films 72b (see FIG. 17C).

Next, a barrier metal 80 of a titanium nitride film of, e.g., a 50 nm-thickness is formed by, e.g. sputtering on the silicon oxide film 76 with the contact holes 78a, 78b formed in.

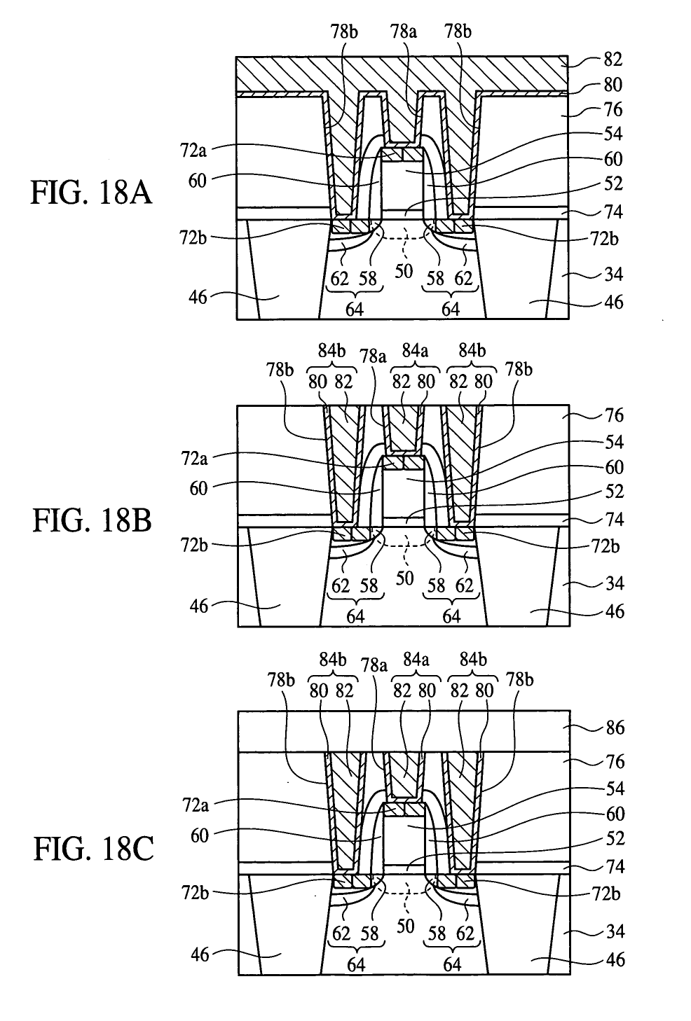

Then, a tungsten film 82 of, e.g. a 400 nm-thickness is formed on the barrier metal 80 by, e.g., CVD (see FIG. 18A).

Next, the tungsten film 82 and the barrier metal 80 are polished by, e.g., CMP until the surface of the silicon oxide film 76 is exposed. Thus, the contact plugs 84a, 84b are formed of the barrier metal 80 and the tungsten film 82 respectively in the contact holes 78a, 78b (see FIG. 18B).

Next, an inter-layer insulation film 86 is formed on the entire surface (see FIG. 18C).

After the inter-layer insulation film 86 has been formed, interconnection layers (not illustrated) are suitably formed.

Thus, the semiconductor device according to the present embodiment illustrated in FIG. 7 is fabricated.

Next, the results of evaluating the method for fabricating the semiconductor device according to the present embodiment will be explained with reference to FIGS. 19A-19D to 22.

(Evaluation Result (Part 1))

The section of a MOS transistor fabricated by the method for fabricating the semiconductor device according to the present embodiment was observed by a transmission electron microscope, and the roughness in the interface between the silicon substrate and the nickel silicide film was evaluated. The sectional observation was performed for the interface between the source/drain diffused layer of the MOS transistor and the nickel silicide film formed on the source/drain diffused layer thereof.

FIG. 19A is a transmission electron microscopic picture of the observed section of Example 1, i.e., the MOS transistor fabricated by the method for fabricating the semiconductor device according to the present embodiment. In Example 1, a TiN film was formed on a 20 nm-thickness Ni film, and the first thermal processing was performed at 260° C. for 30 seconds. Then, the TiN film and the part of the Ni film, which had not reacted with the Si, were removed, and then the second thermal processing was performed at 450° C. for 30 seconds.

FIG. 19B is a transmission electron microscopic picture of the observed section of Control 1. In Control 1, a TiN film was formed on a 10 nm-thickness Ni film, and thermal processing of 400° C. and 30 seconds was performed once.

FIG. 19C is a transmission electron microscopic picture of the observed section of Control 2. In Control 2, a TiN film was formed on a 10 nm-thickness Ni film, and the first thermal processing was performed at 280° C. for 30 seconds. Then, the TiN film and the part of the Ni film, which had not reacted with the Si, were selectively removed, and then the second thermal processing was performed at 450° C. for 30 seconds.

FIG. 19D is a transmission electron microscopic picture of the observed section of Control 3. In Control 3, a TiN film was formed on a 10 nm-thickness Ni film, and the first thermal processing was performed at 260° C. for 30 seconds. Then, the TiN film and the part of the Ni film, which had not reacted with the Si, were selectively removed, and then the second thermal processing was performed at 450° C. for 30 seconds.

In Controls 1 to 3 shown in FIGS. 19B to 19D, it is observed that NiSi₂ crystals 92 of high resistance are formed inhomogeneously near the interface between the source/drain diffused layer 88 and the NiSi film 90. That is, in Controls 1 to 3, the NiSi phase and the NiSi₂ phase are mixed in the nickel silicide film formed on the source/drain diffused layer. Low annealing alone without making the Ni film thick cannot suppress the NiSi₂ spikes.

In contrast to these, in Example 1 shown in FIG. 19A, such NiSi₂ crystals were not observed. That is, in Example 1, the nickel silicide film formed on the source/drain diffused layer is formed of nickel silicide alone of the NiSi phase alone.

As evident from the comparison among the electron microscopic pictures, it is found that the roughness in the interface between the source/drain diffused layer 88 and the NiSi film 90 is much small in Example 1 in comparison with Controls 1 to 3.

Based on the above-described result of the sectional observation with a transmission electron microscope, the method for fabricating the semiconductor device according to the present embodiment can form the NiSi film of good quality while suppressing the formation of the NiSi₂ film, and it has been confirmed that the roughness in the interface between the silicon substrate and the NiSi film can be decreased.

(Evaluation Result (Part 2))

The junction leak current of the source/drain diffused layer of a MOS transistor fabricated by the method for fabricating the semiconductor device according to the present embodiment was measured. The junction leak current was measured on the p type source/drain diffused layer of a PMOS transistor with boron ion-implanted.

In the measurement, as illustrated in FIG. 20, a negative voltage was applied to a source/drain diffused layer 64 on one side of the gate electrode 54 via a contact plug 84b and an electrode pad 94a. A positive voltage was applied to an n type well 40 where no source/drain diffused layer is formed on the other side of the gate electrode 54 via a contact plug 84b and an electrode pad 94b. Then, a junction leak current which flows when an invert bias was applied between the source/drain diffused layer 64 and the well 40 with the gate electrode 54 therebetween was measured. In each of Example 2 and Controls 4 to 6 which will be described later, the junction leak current was measured on a plurality of samples, and the cumulative probabilities of the samples were plotted. FIG. 21 is a graph of the measured result. On the horizontal axis, the components of the junction leak current of the source/drain diffused layers near the gate electrodes are taken, and on the vertical axis, the cumulative probabilities are taken.

In FIG. 21, the ▾ marked plots indicate the measured result of Example 2, i.e., the method for fabricating the semiconductor device according to the present embodiment. In Example 2, a TiN film is formed on a 20 nm-thickness Ni film, and the first thermal processing was performed at 270° C. for 30 seconds. Next, the TiN film and the part of the Ni film, which had not reacted with the Si, were selectively removed by cleaning with ammonia/hydrogen peroxide mixture and sulfuric acid/hydrogen peroxide mixture, and then the second thermal processing was performed at 500° C. for 30 seconds.

In FIG. 21, the ● marked plots indicate the measured result of Control 4 in which a relatively thin Ni film was formed, and the thermal processing was performed once. In Control 4, a TiN film was formed on a 10 nm-thickness Ni film, and the thermal processing was performed once at 400° C. for 30 seconds. Then, the TiN film and the part of the Ni film, which had not reacted with the Si were selectively removed by cleaning with ammonia/hydrogen peroxide mixture and sulfuric acid/hydrogen peroxide mixture.

In FIG. 21, the Δ marked plots indicate the measured result of Control 5 in which a relatively thin Ni film was formed, and the thermal processing was performed twice. In Control 5, a TiN film was formed on a 10 nm-thickness Ni film, and the first thermal processing was performed at 300° C. for 30 seconds. Then, after the TiN film and the part of the Ni film, which had not reacted with the Si, were selectively removed by cleaning with ammonia/hydrogen peroxide mixture and sulfuric acid/hydrogen peroxide mixture, the second thermal processing was performed at 500° C. for 30 seconds.

In FIG. 21, the ▪ marked plots indicate the measured result of Control 6 in which a cobalt silicide (CoSi₂) film was formed in place of nickel silicide film. In Control 6, as the metal film for the silicidation, a 4 nm-thickness Co film was formed in place of an Ni film, and the CoSi₂ film was formed by the thermal processing.

As evident from the comparison among the plots of the Example 2 and the Controls, in Example 2, in which the Ni film was formed in a relatively large thickness of 20 nm, and the first thermal processing was performed at a relatively low temperature of 270° C., the junction leak current is very small in comparison with Controls 4 and 5, in which the Ni film was formed in a small thickness of 10 nm. The junction leak current of Example 2 is decreased to be comparable with that of Control 6, in which the CoSi₂ film was formed.

Based on the results of Controls 4 and 5, it can be found that when the Ni film is formed relatively thin, the junction leak current cannot be sufficiently decreased irrespective of the height of the temperature of the first thermal processing.

(Evaluation Result (Part 3))

Furthermore, the sheet resistance of the gate electrode was measured on a MOS transistor fabricated by the method for fabricating the semiconductor device according to the present embodiment. The MOS transistor was a PMOS transistor. The dopant impurity ion-implanted in the gate electrode was boron. The gate length of the gate electrode was 40 nm. In each of Example 2 and Controls 4 to 6, the sheet resistance was measured on a plurality of samples, and cumulative probabilities of the samples were plotted. FIG. 22 is a graph of the measured result. On the horizontal axis, the sheet resistance of the gate electrodes are taken, and on the vertical axis, the cumulative probabilities are taken. In FIG. 22, the ▾ marked plots indicate the measured result Example 2, the ● marked plots indicate the measured result of Control 4, the Δ marked plots indicate the measured result of Control 5, and the ▪ marked plots indicate the measured result of Control 6.

As evident from the comparison among the respective plots, in Example 2, the sheet resistance is much smaller in comparison with that of Control 5 in which the Ni film was formed relatively thin. The sheet resistance of Example 2 is decreased to be substantially equal to or lower than that of Control 6, in which the CoSi₂ film was formed.

Based on the above-described measured results of the junction leak current and the sheet resistance, it has been confirmed that the method for fabricating the semiconductor device according to the present embodiment can decrease the junction leak current of the source/drain diffused layer and the sheet resistance of the upper side of the gate electrode with the silicide film formed on.

As described above, according to the present embodiment, the Ni film 66 is formed in a prescribed thickness which is relatively thick, a part of the Ni film 66 on the lower side is reacted with Si by the first thermal processing to form the Ni₂Si films 70a, 70b, the part of the Ni film 66, which has not reacted with the Si, is removed, and then the Ni₂Si films 70a, 70b are reacted with Si by the second thermal processing, whereby the NiSi films 72a, 72b of good quality can be formed in a required film thickness while the formation of the NiSi₂ film of high resistance is suppressed. Accordingly, the roughness in the interface between the gate electrode 54 and the NiSi film 72a and in the interface between the source/drain diffused layers 64 and the NiSi films 72b can be made small, and the dispersion of the sheet resistance of the surface of the gate electrode 54 and the surface of the source/drain diffuse layers 64 can be suppressed. Also, the junction leak current can be suppressed.

(A Modification)

The method for fabricating the semiconductor device according to a modification of the present embodiment will be explained.

The method for fabricating the semiconductor device according to the present modification is characterized in that in the method for fabricating the semiconductor device according to the above-described embodiment, the step of forming the Ni film 66 to the step of performing the first thermal processing are continuously performed without exposure to the atmospheric air.

The steps up to the step of forming the source/drain diffused layers 64 are the same as of the method for fabricating the semiconductor device according to the above-described embodiment illustrated in FIGS. 8A to 15A, and their explanation will be omitted.

Next, native oxide films formed on the surface of the gate electrode 54 and the surface of the source/drain diffused layers 64 are removed by the processing with, e.g., hydrofluoric acid.

Next, the Ni film 66 of, e.g., a 20 nm-thickness is formed on the entire surface. The film thickness of the Ni film 66 is above 17 nm including 17 nm. Preferably, the film thickness of the Ni film 66 is below 200 nm including 200 nm because the part of the Ni film 66, which has not reacted with the Si must be removed after the silicidation.

Here, the Ni film 66 is formed in a film forming apparatus which can form and thermally process plural kinds of metal films continuously in one and the same chamber without exposure to the atmospheric air. In such film forming apparatus, the metal films are formed by, e.g., sputtering, deposition, etc. Thus, the Ni film 66 and the protection film 68 of a TiN film, etc. formed on the Ni film 66, and the first thermal processing are continuously performed without exposure to the atmospheric air.

Then, in the chamber, where the Ni film 66 has been formed, the protection film 68 of a TiN film of, e.g., a 5-50 nm-thickness is continuously formed. The protection film 68 is not essentially formed of a TiN film. The protection film 68 may be formed of a Ti film of, e.g., a 5-30 nm thickness.

In the present modification, after the Ni film 66 has been formed, the substrate with the Ni film 66 exposed is not transferred nor subjected to processing in another apparatus, but the protection film 68 is formed continuously in the chamber where the Ni film 66 has been formed. Accordingly, the secondary contamination with the Ni can be effectively prevented.

Then, in the chamber where the Ni film 66 and the protection film 68 have been formed, the first thermal processing for the silicidation is continuously performed by, e.g., RTA at, e.g., 270° C. and for 30 seconds. Thus, the Ni in a part of the Ni film 66 on the lower side and the Si in a part of the gate electrode 64 on the upper side are reacted with each other, and the Ni in a part of the Ni film 66 on the lower side and the Si in a part of the source/drain diffused layers 64 on the upper side are reacted with each other. Thus the Ni₂Si films 70a, 70b are formed on the gate electrode 54 and on the source/drain diffused layers 64.

The steps following the first thermal processing are the same as those of the method for fabricating the semiconductor device according to the above-described embodiment, and their explanation will be omitted.

As described above, in the method for fabricating the semiconductor device according to the present modification, the step of forming the Ni film 66 to the step of performing the first thermal processing are performed continuously in one and the same apparatus without exposure to the atmospheric air. Accordingly, the formation of the Ni film 66 to the first thermal processing can be performed without exposing the surface of the Ni film 66 to the atmospheric air. Thus, the oxidation of the surface of the Ni film 66 can be suppressed, and the silicide film can have good quality. Another thermal processing apparatus is not required for the first thermal processing, which can improve the throughput of the fabrication steps.

The protection film 68 is formed continuously in the chamber where the Ni film 66 has been formed, which permits the secondary contamination with the Ni can be effectively prevented.

### A Second Embodiment

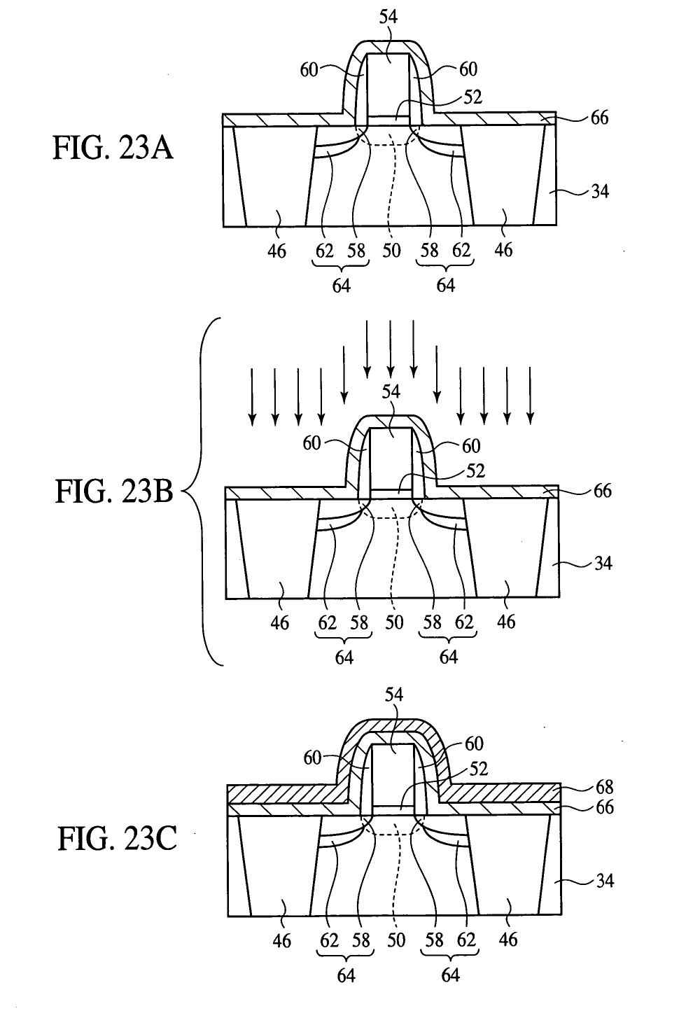

The semiconductor device according to a second embodiment of the present invention and the method for fabricating the semiconductor device will be explained with reference to FIGS. 23A-23C. FIGS. 23A-23C are sectional views of the semiconductor device according to the present embodiment in the steps of the method for fabricating the semiconductor device, which illustrate the method. The same members of the present embodiment as those of the semiconductor device and the method for fabricating the same according to the first embodiment illustrated in FIGS. 7 to 18A-18C are represented by the same reference numbers not to repeat or to simplify their explanation.

The semiconductor device according to the present embodiment is substantially the same as the semiconductor device according to the first embodiment in the structure but is different from the latter in the method for fabricating the semiconductor device.

That is, the method for fabricating the semiconductor device according to the present embodiment is characterized in that in the method for fabricating the semiconductor device according to the first embodiment, before the first thermal processing for the silicidation, the Ni film 66 is made amorphous by the implantation of Ni ions.

First, the steps up to the step of forming a source/drain diffused layers 64 are the same as those of the method for fabricating the semiconductor device according to the first embodiment illustrated in FIGS. 8A to 15A, and their explanation will be omitted.

Next, native oxide films formed on the surface of the gate electrode 54 and the surface of the source/drain diffused layers 64 are removed by the processing with, e.g., hydrofluoric acid.

Next, a Ni film 66 of, e.g., a 20 nm-thickness is formed on the entire surface by sputtering using a Ni target (see FIG. 23A). The film thickness of the Ni film 66 is above 17 nm including 17 nm. The film thickness of the Ni film 66 is preferably below 200 nm including 200 nm because the part of the Ni film 66 which has not reacted with the Si must be removed without failure after the silicidation.

Then, before the first thermal processing for the silicidation, Ni ions are implanted into the Ni film 66 (see FIG. 23B). Thus, the Ni film 66 is made amorphous. Conditions for the Ni ion implantation are suitably set in accordance with a film thickness of the Ni film 66. When the film thickness of the Ni film 66 is, e.g., 20 nm, as a condition for the ion implantation, the acceleration energy is, e.g., 5 keV. When the film thickness of the Ni film 66 is, e.g., 200 nm, as a condition for the ion implantation, the acceleration energy is, e.g., 500 keV. The dose can be a quantity which can make the Ni film 66 amorphous and is, e.g., 1×10¹⁴-1×10¹⁵ cm⁻².

Then, a protection film 68 of a TiN film of, e.g., a 5-50 nm-thickness is formed on the amorphous Ni film 66 by, e.g., PVD (see FIG. 23C). The protection film 68 is for preventing the oxidation of the Ni film 66 and a nickel silicide film formed thereon. The protection film 68 is not essentially formed of TiN film. The protection film 68 may be formed of a Ti film of, e.g., a 5-30 nm-thickness.

The steps following the formation of the protection film 68 are the same as those of the method for fabricating the semiconductor device according to the first embodiment illustrated in FIGS. 16A to 18C, and their explanation will be omitted.

As described above, in the method for fabricating the semiconductor device according to the present embodiment, Ni ions are ion-implanted into the Ni film 66 before the first thermal processing for the silicidation is performed, whereby the Ni film 66 is made amorphous. Accordingly, in the first thermal processing for the silicidation, the Ni in the Ni film 66 reacts with the Si, diffusing at a higher rate than the Ni in the Ni film which is not made amorphous. Accordingly, in the first thermal processing, the Ni₂Si films 70a, 70b can be formed efficiently and stably. Thus, the NiSi film 72a, 72b of good quality can be formed while the formation of the NiSi₂ film can be further effectively suppressed.

In the present embodiment, the Ni film 66 is made amorphous by the Ni ion implantation. However, the method for making the Ni film 66 amorphous is not limited to the ion implantation, and Ni film 66 may be made amorphous by depositing Ni at a very high sputtering rate of, e.g., above 1 nm/second including 1 nm/second, or the Ni film 66 may be made amorphous by the sputtering under a high argon (Ar) pressure of, e.g., above 5 mTorr including 5 mTorr. Even when the Ni film 66 is nano-grained by such processing, the same effect as that obtained by making the Ni film 66 amorphous can be obtained. The nano-graining means here reducing the grain diameter of the grains forming the metal film to the nano-meter order.

Japanese published unexamined patent application No. Hei 09-251967 (1997) discloses that in the salicide process using a Co film, for the purpose of suppressing the generation of abnormal growth (spikes) of CoSiₓ, which is a cause for the generation of the junction leak, a silicon substrate is made amorphous before the Co film is formed on the silicon substrate. However, the method disclosed in Japanese published unexamined patent application No. Hei 09-251967 (1997), in which a silicon substrate is made amorphous, is irrelevant to the method for fabricating the semiconductor device according to the present embodiment, in which the Ni film is made amorphous in the salicide process using Ni film.

### Modified Embodiments

The present invention is not limited to the above-described embodiments and can cover other various modifications.

For example, in the above-described embodiments, the salicide process is performed to form the NiSi films 72a, 72b on both the gate electrode 54 and the source/drain diffused layers 64. However, in the present invention, the NiSi films 72a, 72b are not essentially formed on both the gate electrode 54 and the source/drain diffused layers 64, and the NiSi film may be formed on either of the gate electrode 54 or the source/drain diffused layers 64.

In the above-described embodiments, the first and the second thermal processing is performed by RTA. However, the first and the second thermal processing is not essentially limited to the thermal processing by RTA. For example, the first and the second thermal processing may be performed by furnace annealing, spike annealing or others. The thermal processing by RTA, the furnace annealing and the spike annealing may be suitably combined.

The conditions for the first thermal processing are not limited to those of the above-described embodiments. In the first thermal processing, the thermal processing temperature may be, e.g., 200-400° C. The processing time may be, e.g., 10 seconds-60 minutes.

The conditions for the second thermal processing are not limited to those of the above-described embodiments. In the second thermal processing, the thermal processing temperature may be substantially equal to or higher than that of the first thermal processing, specifically, e.g., 350-650° C. The thermal processing time may be, e.g., 10 seconds-60 minutes. Otherwise, the second thermal processing may be performed by spike annealing of 450-650° C.

In the above-described embodiments, the Ni film 66 is formed by sputtering. However, the Ni film 66 may not be essentially formed by sputtering. The Ni film 66 may be formed by, e.g., vapor deposition, e.g., electron beam vapor deposition or others, other than the sputtering.

In the above-described embodiments, the protection film 68 is formed on the Ni film 66 but may not be formed. When the substrate with the Ni film formed on is mounted with the Ni film exposed on a cassette for transporting substrates or loaded in the furnace of an RTA apparatus or the chamber of a film deposition apparatus, the cassette, the furnace or the chamber are contaminated with the Ni, and particles of the Ni often adhere to other substrates which are later mounted on the cassette or loaded in the furnace of the RTA apparatus or the chamber of the film deposition apparatus. The protection film 68 formed on the Ni film 66 can prevent the secondary contamination with the Ni.

1. A semiconductor device comprising:
a gate electrode formed on a semiconductor substrate;
a source/drain diffused layer formed in the semiconductor substrate on both sides of the gate electrode; and
a silicide film formed on the source/drain diffused layer,
the silicide film being formed of nickel monosilicide, and
a film thickness of the silicide film being below 20 nm including 20 nm.

2. A semiconductor device according to claim 1, further comprising
another silicide film formed on the gate electrode,
said another silicide film being formed of nickel monosilicide, and
a film thickness of said another silicide film being below 20 nm including 20 nm.

3. A method for fabricating a semiconductor device comprising:
the step of forming a gate electrode on a semiconductor substrate;
the step of forming a source/drain diffused layer in the semiconductor substrate on both sides of the gate electrode;
the step of forming a nickel film on the source/drain diffused layer;
the first thermal processing step of reacting by thermal processing a part of the nickel film on the lower side and a part of the source/drain diffused layer on the upper side with each other to form a nickel silicide film on the source/drain diffused layer;
the step of etching off selectively a part of the nickel film, which has not reacted; and
the second thermal processing step of reacting further the nickel silicide film and a part of the source/drain diffused layer on the upper side with each other.

4. A method for fabricating a semiconductor device according to claim 3, wherein
in the step of forming the nickel film, the nickel film is formed in a thickness of above 17 nm including 17 nm.

5. A method for fabricating a semiconductor device according to claim 3, wherein
in the step of forming the nickel film, the nickel film is formed further on the gate electrode,
in the first thermal processing step, a part of the nickel film on the lower side and a part of the gate electrode on the upper side are reacted with each other to form a nickel silicide film further on the gate electrode,
in the step of etching off selectively the part of the nickel film which has not reacted, a part of the nickel film on the gate electrode, which has not reacted is selectively etched off, and
in the second thermal processing step, the nickel silicide film on the gate electrode and a part of the gate electrode on the upper side are further reacted with each other.

6. A method for fabricating a semiconductor device according to claim 4, wherein
in the step of forming the nickel film, the nickel film is formed further on the gate electrode,
in the first thermal processing step, a part of the nickel film on the lower side and a part of the gate electrode on the upper side are reacted with each other to form a nickel silicide film further on the gate electrode,
in the step of etching off selectively the part of the nickel film which has not reacted, a part of the nickel film on the gate electrode, which has not reacted is selectively etched off, and
in the second thermal processing step, the nickel silicide film on the gate electrode and a part of the gate electrode on the upper side are further reacted with each other.

7. A method for fabricating a semiconductor device according to claim 3, wherein
a temperature of the thermal processing in the second thermal processing step is higher than a temperature of the thermal processing in the first thermal processing step.

8. A method for fabricating a semiconductor device according to claim 4, wherein
a temperature of the thermal processing in the second thermal processing step is higher than a temperature of the thermal processing in the first thermal processing step.

9. A method for fabricating a semiconductor device according to claim 3, wherein
a temperature of the thermal processing in the first thermal processing step is 200-400° C., and
a temperature of the thermal processing in the second thermal processing step is 350-650° C.

10. A method for fabricating a semiconductor device according to claim 4, wherein
a temperature of the thermal processing in the first thermal processing step is 200-400° C., and
a temperature of the thermal processing in the second thermal processing step is 350-650° C.

11. A method for fabricating a semiconductor device according to claim 3, wherein
in the second thermal processing step, the thermal processing is performed by spike annealing of 450-650° C.

12. A method for fabricating a semiconductor device according to claim 4, wherein
in the second thermal processing step, the thermal processing is performed by spike annealing of 450-650° C.

13. A method for fabricating a semiconductor device according to claim 3, wherein
in the step of forming the nickel film, the nickel film is formed by sputtering.

14. A method for fabricating a semiconductor device according to claim 4, wherein
in the step of forming the nickel film, the nickel film is formed by sputtering.

15. A method for fabricating a semiconductor device according to claim 3, further comprising after the step of forming the nickel film and before the first thermal processing step,
the step of making the nickel film amorphous.

16. A method for fabricating a semiconductor device according to claim 4, further comprising after the step of forming the nickel film and before the first thermal processing step,
the step of making the nickel film amorphous.

17. A method for fabricating a semiconductor device according to claim 15, wherein
in the step of making the nickel film amorphous, the nickel film is made amorphous by ion-implanting nickel ions into the nickel film.

18. A method for fabricating a semiconductor device according to claim 17, wherein
in the step of making the nickel film amorphous, the nickel ions are ion-implanted into the nickel film at a 5-500 keV acceleration energy and a 1×10¹⁴-1×10¹⁵ cm⁻² dose.

19. A method for fabricating a semiconductor device according to claim 3, further comprising after the step of forming the nickel film and before the first thermal processing step,
the step of forming on the nickel film a protection film for preventing the oxidation of the nickel film.

20. A method for fabricating a semiconductor device according to claim 3, wherein
the step of forming the nickel film to the first thermal processing step are continuously performed without exposure to the atmospheric air.
